(19) United States
(12) Patent Application Publication
(10) Pub. No.: US 2025/0185416 A1
(43) Pub. Date: Jun. 5, 2025

(54) DISPLAY DEVICE AND METHOD OF MANUFACTURING THE SAME

(71) Applicant: SAMSUNG ELECTRONICS., LTD., Suwon-si (KR)

(72) Inventors: Joohun HAN, Suwon-si (KR); Nakhyun KIM, Suwon-si (KR); Sunil KIM, Suwon-si (KR); Joosung KIM, Suwon-si (KR); Junghun PARK, Suwon-si (KR); Dongchul SHIN, Suwon-si (KR); Eunsung LEE, Suwon-si (KR); Junhee CHOI, Suwon-si (KR)

(73) Assignee: SAMSUNG ELECTRONICS., LTD., Suwon-si (KR)

(21) Appl. No.: 18/970,174

(22) Filed: Dec. 5, 2024

(30) Foreign Application Priority Data
Dec. 5, 2023 (KR) 10-2023-0174937

(51) Int. Cl. H10H 20/813; G02B 27/01; H10H 20/01; H10H 20/816; H10H 20/84; H10H 29/01

(52) U.S. Cl. CPC H10H 20/8131; G02B 27/0172; H10H 20/017; H10H 20/8162; H10H 20/84; H10H 29/034; G02B 2027/0178

(57) ABSTRACT

A display device includes a first epitaxial structure vertically stacked, a first light emitting element including a second epitaxial structure and a third epitaxial structure, a second light emitting element spaced apart from the first light emitting element and including the first epitaxial structure, a first passivation layer arranged to surround a sidewall of the first light emitting element, and a second passivation layer arranged to surround a sidewall of the second light emitting element. Each of the first epitaxial structure, the second epitaxial structure, and the third epitaxial structure may include a structure in which a first semiconductor layer of a first conductivity type, a carrier blocking layer, an active layer, and a second semiconductor layer of a second conductivity type are sequentially stacked.

### CROSS-REFERENCE TO RELATED APPLICATION

This application is based on and claims priority under 35 U.S.C. § 119 to Korean Patent Application No. 10-2023-0174937, filed on Dec. 5, 2023, in the Korean Intellectual Property Office, the disclosure of which is incorporated by reference herein in its entirety.

### BACKGROUND

### 1. Field

The disclosure relates to a display device and a method of manufacturing the same.

### 2. Description of the Related Art

Light emitting diodes (LEDs) are considered as next-generation light sources due to their advantages such as long life, low power consumption, fast response speed, and environmental friendliness compared to conventional light sources. Due to these and other advantages, the industrial demand for LEDs is increasing, and as such, LEDs are generally applied to and/or used in various products such as lighting devices and backlights of display devices.

Recently, monolithic RGB LEDs have been developed. However, since non-emission recombination occurs in a monolithic RGB LED manufacturing process, the luminous efficiency of RGB LEDs may be impaired and a passivation process is used to minimize this impairment.

### SUMMARY

According to one or more aspects of the disclosure, there is provided a display device with improved luminous efficiency and a method of manufacturing the same.

Additional aspects will be set forth in part in the description which follows and, in part, will be apparent from the description, or may be learned by practice of the presented embodiments of the disclosure.

According to an aspect of the disclosure, there is provided a display device including: a first light emitting element including a first epitaxial structure, a second epitaxial structure, and a third epitaxial structure; a second light emitting element including a fourth epitaxial structure, the second light emitting element spaced apart from the first light emitting element; a first passivation layer provided on a sidewall of the first light emitting element; and a second passivation layer provided on a sidewall of the second light emitting element, wherein each of the first epitaxial structure, the second epitaxial structure, the third epitaxial structure and the fourth epitaxial structure includes a first semiconductor layer of a first conductivity type, a carrier blocking layer, an active layer, and a second semiconductor layer of a second conductivity type are sequentially arranged.

The second passivation layer may be further provided on a sidewall of the first passivation layer.

The first light emitting element may be configured to emit red light and the first passivation layer includes AlOₓN_{y}.

The second light emitting element may be configured to emit blue light and the second passivation layer includes Ta₂O₅.

A thickness of the first passivation layer may be about 10 nm to about 30 nm.

A thickness of the second passivation layer may be about 10 nm to about 30 nm.

The second passivation layer may include a plurality of layers.

The display device may further include an electron blocking layer provided between the active layer and the second semiconductor layer.

The display device may further include a third light emitting element arranged between the first light emitting element and the second light emitting element and including a fifth epitaxial structure and a sixth epitaxial structure.

According to another aspect of the disclosure, there is provided a method of manufacturing a display device, the method including: forming a vertically stacked epitaxial structure by stacking a first epitaxial structure, a second epitaxial structure, and a third epitaxial structure, each of the first, second and third epitaxial structures having a first semiconductor layer of a first conductivity type, a carrier blocking layer, an active layer, and a second semiconductor layer of a second conductivity type are sequentially stacked on a substrate; etching the vertically stacked epitaxial structure to form a first mesa structure and a second mesa structure, the first mesa structure including a first portion of the first epitaxial structure, a first portion of the second epitaxial structure, and a first portion of the third epitaxial structure and the second mesa structure including a second portion of the first epitaxial structure; forming an electrode on the first mesa structure and the second mesa structure; providing a first passivation layer on sidewalls of the first mesa structure and the second mesa structure; removing the first passivation layer provided on the second mesa structure; and providing a second passivation layer on the sidewall of the second mesa structure.

The providing the second passivation layer may further include providing the second passivation layer on a sidewall of the first passivation layer.

The first mesa structure may have a first height and the second mesa structure has a second height different from the first height.

The method may further include, before the removing of the first passivation layer provided on the second mesa structure, forming a mask on the first passivation layer provided on the first mesa structure.

The method may further include exposing the electrode by etching a portion of the first passivation layer and the second passivation layer.

The method may further include forming an electron blocking layer between the active layer and the second semiconductor layer.

The forming of the first mesa structure and the second mesa structure may further include forming a third mesa structure between the first mesa structure and the second mesa structure, the third mesa structure including a third portion of the first epitaxial structure and a second portion the second epitaxial structure which are vertically stacked.

The first mesa structure may form a light emitting element configured to emit red light and the first passivation layer includes AlOₓN_{y}.

The second mesa structure may form a light emitting element configured to emit blue light and the second passivation layer includes Ta₂O₅.

According to another aspect of the disclosure, there is provided an augmented reality device including: a projection system including a display device configured to form an image; and an optical system for guiding the image from the projection system to the eyes of a user, wherein the display device includes: a first light emitting element including a first epitaxial structure, a second epitaxial structure, and a third epitaxial structure; a second light emitting element including a fourth epitaxial structure, the second light emitting element spaced apart from the first light emitting element; a first passivation layer provided on a sidewall of the first light emitting element; and a second passivation layer provided on a sidewall of the second light emitting element, wherein each of the first epitaxial structure, the second epitaxial structure, the third epitaxial structure and the fourth epitaxial structure includes a first semiconductor layer of a first conductivity type, a carrier blocking layer, an active layer, and a second semiconductor layer of a second conductivity type are sequentially arranged.

The first light-emitting element may be configured to emit red light, the second light-emitting element may be configured to emit blue light, the first passivation layer may include AlOₓN_{y} and the second passivation layer may include Ta₂O₅.

### BRIEF DESCRIPTION OF DRAWINGS

The above and other aspects, features and advantages of certain embodiments of the disclosure will be more apparent from the following description taken in conjunction with the accompanying drawings, in which:

FIG. 1 is a cross-sectional view illustrating a display device according to an embodiment;

FIG. 2 is a cross-sectional view illustrating a display device according to an embodiment;

FIG. 3 is a cross-sectional view illustrating a display device according to an embodiment;

FIGS. 4A to 4K are cross-sectional views illustrating a method of manufacturing a display device according to an embodiment;

FIGS. 5A to 5E are cross-sectional views illustrating a portion of a method of manufacturing a display device according to an embodiment;

FIGS. 6 and 7 are graphs illustrating a change in a photoluminescence intensity according to a wavelength of a light emitting element according to an embodiment and a wavelength of a light emitting element according to a comparative example;

FIG. 8 is a schematic block diagram of an electronic device according to an embodiment;

FIG. 9 illustrates an example in which a display device according to an embodiment is applied to a mobile device;

FIG. 10 illustrates an example in which a display device according to an embodiment is applied to a display device for a vehicle;

FIG. 11 illustrates an example in which a display device according to an embodiment is applied to a pair of augmented reality glasses;

FIG. 12 illustrates an example in which a display device according to an embodiment is applied to a signage; and

FIG. 13 illustrates an example in which a display device according to an embodiment is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a display device and a method of manufacturing the same will be described in detail with reference to the accompanying drawings. In the following drawings, the same reference numerals refer to the same components and the size of each component in the drawings may be exaggerated for clarity and convenience of description. In addition, the embodiments described below are merely exemplary and various modifications are possible from these embodiments.

Hereinafter, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that the part may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in an appropriate order and are not necessarily limited to the described order.

The connection or connection members of lines between the components shown in the drawings exemplarily represent functional connection and/or physical or circuit connections and may be replaceable or represented as various additional functional connections, physical connections, or circuit connections in an actual device.

The use of all examples or exemplary terms is merely for describing a technical idea in detail and the scope is not limited to the examples or exemplary terms unless limited by the claims.

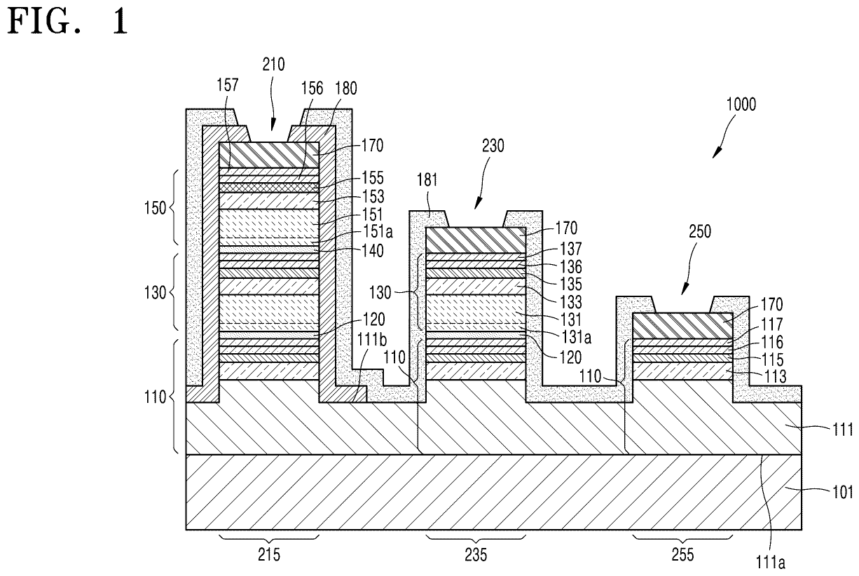

FIG. 1 is a cross-sectional view illustrating a display device according to an embodiment.

Referring to FIG. 1, a display device 1000 may include a first light emitting element 215, a second light emitting element 235, and a third light emitting element 255. The first light emitting element 215 may include a first epitaxial structure 110, a second epitaxial structure 130 and a third epitaxial structure 150, which are vertically stacked on a substrate 101, and the third light emitting element 255 light emitting may include the first epitaxial structure 110. Here, the first epitaxial structure 110 of the third light emitting element 255 may be referred to as a fourth epitaxial structure. For example, the first epitaxial structure 110 of the third light emitting element 255 may be a separate structure from the first epitaxial structure 110 of the first light emitting element 215. However, the first epitaxial structure 110 of the third light emitting element 255 and the first epitaxial structure 110 of the first light emitting element 215 may have same elements and/or same arrangement of elements. The third light emitting element 255 may be spaced apart from the first light emitting element 215. The display device 1000 may further include a first passivation layer 180 provided on the first light emitting element 215 and a second passivation layer 181 provided on the third light emitting element 255. For example, the first passivation layer 180 may be arranged to surround a sidewall of the first light emitting element 215 and the second passivation layer 181 may be arranged to surround a sidewall of the third light emitting element 255. According to an embodiment, the first passivation layer 180 may be provided directly on the sidewall of the first light emitting element 215 and the second passivation layer 181 may be provided directly on the sidewall of the third light emitting element 255. However, the disclosure is not limited thereto, and as such, according to another embodiment, one or more other layers may be provided between the first passivation layer 180 may be provided directly on the sidewall of the first light emitting element 215, and between the second passivation layer 181 and the sidewall of the third light emitting element 255.

According to an embodiment, the second light emitting element 235 may include the first epitaxial structure 110 and the second epitaxial structure 130. Here, the first epitaxial structure 110 of the third light emitting element 255 may be referred to as a fifth epitaxial structure and the second epitaxial structure 130 of the second light emitting element 255 may be referred to as a sixth epitaxial structure. For example, the first epitaxial structure 110 of the second light emitting element 235 may be a separate structure from the first epitaxial structure 110 of the first light emitting element 215 and the first epitaxial structure 110 of the third light emitting element 255. However, the first epitaxial structure 110 of the second light emitting element 235 and the first epitaxial structure 110 of the first light emitting element 215 may have same elements and/or same arrangement of elements. Also, the second epitaxial structure 130 of the second light emitting element 235 may be a separate structure from the second epitaxial structure 130 of the first light emitting element 215. However, the second epitaxial structure 130 of the second light emitting element 235 and the second epitaxial structure 130 of the first light emitting element 215 may have same elements and/or same arrangement of elements.

The substrate 101 may include, for example, silicon, sapphire, or GaAs. However, the embodiments are not limited thereto and the substrate 101 may include a material other than silicon, sapphire, or GaAs.

According to an embodiment, a buffer layer may be provided between the substrate 101 and the first epitaxial structure 110. In some example cases, the buffer layer may be provided to relieve stress caused by a difference in lattice constant between the substrate 101 and a first semiconductor layer 111 of the first epitaxial structure 110. The buffer layer may be grown to have a crystalline quality using, for example, a chemical vapor deposition (CVD) process, a physical vapor deposition (PVD) process, or an atomic layer deposition (ALD) process. The lattice constant of the buffer layer may have a value between the lattice constant of the substrate 101 and the lattice constant of the first semiconductor layer 111, or may have the same value as the lattice constant of the first semiconductor layer 111. The buffer layer may include, for example, a group III-V compound semiconductor such as GaN, GaP, GaAs, or the like. In addition, the buffer layer may be doped with the same conductivity type as the first semiconductor layer 111. In an example case in which the first semiconductor layer 111 is doped with impurities of an n type, the buffer layer may include n-GaN, n-GaP, or n-GaAs and in an example case in which the first semiconductor layer 111 is doped with impurities of a p type, the buffer layer may include p-GaN, p-GaP, or p-GaAs.

The first epitaxial structure 110 may include a first semiconductor layer 111 of a first conductivity type, a first carrier blocking layer 113, an active layer 115 and a second semiconductor layer 117 of a second conductivity. For example, the first epitaxial structure 110 may include a structure in which the first semiconductor layer 111 of the first conductivity type, the first carrier blocking layer 113, the active layer 115 and the second semiconductor layer 117 of the second conductivity type are sequentially stacked. The first epitaxial structure 110 may further include a second carrier blocking layer 116 between the active layer 115 and the second semiconductor layer 117. The first epitaxial structure may be a structure for blue light emission.

The second epitaxial structure 130 may include a first semiconductor layer 131 of the first conductivity type, a first carrier blocking layer 133, an active layer 135 and a second semiconductor layer 137 of the second conductivity type. For example, the second epitaxial structure 130 may include a structure in which the first semiconductor layer 131 of the first conductivity type, the first carrier blocking layer 133, the active layer 135 and the second semiconductor layer 137 of the second conductivity type are sequentially stacked. The second epitaxial structure 130 may further include a second carrier blocking layer 136 between the active layer 135 and the second semiconductor layer 137. The second epitaxial structure 130 may be a structure for green light emission.

The third epitaxial structure 150 may include a first semiconductor layer 151 of the first conductivity type, a first carrier blocking layer 153, an active layer 155 and a second semiconductor layer 157 of the second conductivity. For example, the third epitaxial structure 150 may include a structure in which the first semiconductor layer 151 of the first conductivity type, the first carrier blocking layer 153, the active layer 155 and the second semiconductor layer 157 of the second conductivity type are sequentially stacked. The third epitaxial structure 150 may further include a second carrier blocking layer 156 between the active layer 155 and the second semiconductor layer 157. The third epitaxial structure 150 may be a structure for red light emission.

The first semiconductor layers 111, 131 and 151 may be doped with impurities of the first conductivity type and the second semiconductor layers 117, 137 and 157 may be doped with impurities of the second conductivity type that is electrically opposite to the first conductivity type. For example, the first semiconductor layers 111, 131 and 151 may be doped with impurities of an n type, the second semiconductor layers 117, 137 and 157 may be doped with impurities of a p type, or the first semiconductor layers 111, 131 and 151 may be doped with impurities of the p type and the second semiconductor layers 117, 137 and 157 may be doped with impurities of the n type. One of the first semiconductor layers 111, 131, 151 and the second semiconductor layers 117, 137 and 157 may be a group III-V compound semiconductor layer doped with impurities of the n type and the other may be a group III-V compound semiconductor layer doped with impurities of the p type.

One of the first carrier blocking layers 113, 133, 153 and the second carrier blocking layers 116, 136 and 156 may be a hole blocking layer (HBL) and the other may be an electron blocking layer (EBL). In an example case in which the first semiconductor layers 111, 131 and 151 are doped with impurities of the n type and the second semiconductor layers 117, 137 and 157 are doped with impurities of the p type, the first carrier blocking layers 113, 133 and 153 may be the HBL and the second carrier blocking layers 116, 136 and 156 may be the EBL. In another example case in which the first semiconductor layers 111, 131 and 151 are doped with impurities of the p type and the second semiconductor layers 117, 137 and 157 are doped with impurities of the n type, the first carrier blocking layers 113, 133 and 153 may be the EBL and the second carrier blocking layers 116, 136 and 156 may be the HBL.

According to an embodiment, the first carrier blocking layers 113, 133 and 153 in the display device 1000 may include a hole blocking layer. Moreover, in each of the first epitaxial structure 110, the second epitaxial structure 130 and the third epitaxial structure 150, an electronic blocking layer may be further provided as the second carrier blocking layers 116, 136 and 156. For example, the second carrier blocking layer 116 may be provided between the active layer 115 and the second semiconductor layer 117, the second carrier blocking layer 136 may be provided between the active layer 135 and the second semiconductor layer 137, the second carrier blocking layer 156 may be provided between the active layer 155 and the second semiconductor layer 157.

The active layers 115, 135 and 155 recombine electrons and holes provided from the first semiconductor layers 111, 131 and 151 and the second semiconductor layers 117, 137 and 157 to generate light. For example, the active layer 115 may recombine electrons and holes provided from the first semiconductor layer 111 and the second semiconductor layer 117, the active layer 135 may recombine electrons and holes provided from the first semiconductor layer 131 and the second semiconductor layer 137, and the active layer 155 may recombine electrons and holes provided from the first semiconductor layer 151 and the second semiconductor layer 157. To this end, the active layers 115, 135 and 155 may have a quantum well structure in which a quantum well is arranged between the barriers. The wavelength of light generated from the active layers 115, 135 and 155 may be determined according to the energy band gap of the material constituting the quantum well in the active layers 115, 135 and 155. The active layers 115, 135 and 155 may have only a single quantum well, but may have a multi-quantum well (MQW) structure in which a plurality of quantum wells are arranged. The energy of the quantum well in the conduction band may be selected to be less than the energy of the barrier. To this end, the barriers and quantum wells in the active layers 115, 135 and 155 may include different compound semiconductors or compound semiconductors having different compositions.

The first semiconductor layers 111, 131 and 151, the active layers 115, 135 and 155, the second semiconductor layers 117, 137 and 157, the first carrier blocking layers 113, 133 and 153 and the second carrier blocking layers 116, 136 and 156 may include, for example, a group III-V compound semiconductor based on GaN. For example, the first semiconductor layers 111, 131 and 151, the active layers 115, 135 and 155 and the second semiconductor layers 117, 137 and 157 may include a group III-V compound semiconductor such as GaN, InGaN, AlInGaN and AlGaInP and the first semiconductor layers 111, 131 and 151 and the second semiconductor layers 117, 137 and 157 may be doped with impurities of a conductivity type opposite to each other. For example, one of the first carrier blocking layers 113, 133 and 153 and the second carrier blocking layers 116, 136 and 156 may include AlGaN and the other may include AlInGaN.

For example, the first semiconductor layer 111, 131 and 151 and the second semiconductor layers 117, 137 and 157 may include GaN and may be doped with impurities of a conductivity type opposite to each other. That is, the first semiconductor layers 111, 131 and 151 may include a GaN layer doped with the n type and the second semiconductor layers 117, 137 and 157 may include a GaN layer doped with the p type. As another example, that is, the first semiconductor layers 111, 131 and 151 may include a GaN layer doped with the p type and the second semiconductor layers 117, 137 and 157 may include a GaN layer doped with the n type. The active layers 115, 135 and 155 may include, for example, InGaN and a composition ratio of In and Ga may vary according to a desired emission wavelength.

In each of the first epitaxial structure 110, the second epitaxial structure 130 and the third epitaxial structure 150, the active layers 115, 135 and 155 may have, for example, a stacked structure of a first barrier-quantum well-second barrier. The first barrier may be, for example, a GaN barrier, in which Si may or may not be doped. The quantum well may have a single quantum well structure or a multi-quantum well structure. For example, the quantum well may include a single stack structure or a plurality of stack structures of InGaN/GaN or InGaN/GaN/AlGaN. In InₓGa₁₋ₓN of the stacked structure forming the quantum well, the composition ratio of In and Ga may vary depending on the emission wavelength. GaN of the stacked structure forming the quantum well may or may not be doped with Si.

In an example case in which the first epitaxial structure 110, the second epitaxial structure 130 and the third epitaxial structure 150 generate blue light, green light and red light, respectively, the active layer 135 of the second epitaxial structure 130 and the active layer 155 of the third epitaxial structure 150 may or may not include an AlGaN layer and the active layer 115 of the first epitaxial structure 110 may not include AlGaN. That is, in the active layer 135 of the second epitaxial structure 130 and the active layer 155 of the third epitaxial structure 150, the quantum well may include a single stack structure or a plurality of stack structures of InₓGa₁₋ₓN/GaN or InₓGa₁₋ₓN/GaN/AlGaN and in the active layer 115 of the first epitaxial structure 110, the quantum well may include a single stack structure or a plurality of stack structures of InₓGa₁₋ₓN/GaN.

In an example case in which the first epitaxial structure 110 generates blue light, x in InₓGa₁₋ₓN constituting the active layer 115 may be, for example, about 0.16 to about 0.17. In an example case in which the second epitaxial structure 130 generates green light, x in InₓGa₁₋ₓN constituting the active layer 135 may be, for example, about 0.23 to about 0.24. In an example case in which the third epitaxial structure 150 generates red light, x at InₓGa₁₋ₓN of the active layer 155 may be, for example, about 0.34 to about 0.35. Here, the first epitaxial structure 110, the second epitaxial structure 130 and the third epitaxial structure 150 generate blue light, green light and red light, respectively, but embodiments are not limited thereto. Hereinafter, for convenience, blue light is generated in the first epitaxial structure 110, green light in the second epitaxial structure 130 and red light in the third epitaxial structure 150, for example.

Meanwhile, in the first epitaxial structure 110, the second epitaxial structure 130 and the third epitaxial structure 150, one of the first carrier blocking layers 113, 133 and 153 and the second carrier blocking layers 116, 136 and 156 is an EBL and the other is an HBL. For example, the EBL may include a p type AlGaN, the HBL may include AlInGaN and a composition ratio of Al in the HBL may be about 0.2 or less.

Meanwhile, in the display device according to an embodiment, a tunnel junction may be further formed between adjacent epitaxial structures. To this end, a junction layer doped with a high concentration may be further formed in the same conductivity type as the first semiconductor layer of another epitaxial structure adjacent to the second semiconductor layer of one epitaxial structure.

For example, a tunnel junction may be further formed between the second semiconductor layer 117 of the first epitaxial structure 110 and the first semiconductor layer 131 of the second epitaxial structure 130 and between the second semiconductor layer 137 of the second epitaxial structure 130 and the first semiconductor layer 151 of the third epitaxial structure 150. To this end, between the second semiconductor layer 117 of the first epitaxial structure 110 and the first semiconductor layer 131 of the second epitaxial structure 130 and between the second semiconductor layer 137 of the second epitaxial structure 130 and the first semiconductor layer 151 of the third epitaxial structure 150, respectively, a first junction layer 120 and a second junction layer 140 doped with the same conductivity type as the first semiconductor layers 131 and 151 may be further formed. The first junction layer 120 and the second junction layer 140 may be provided to form a tunnel junction within a range of, for example, about 10 nm or less. Here, an example in which both the first junction layer 120 and the second junction layer 140 are provided is described, but the embodiments are not limited thereto. For example, a junction layer may be formed only in any one between the second semiconductor layer 117 of the first epitaxial structure 110 and the first semiconductor layer 131 of the second epitaxial structure 130 and between the second semiconductor layer 137 of the second epitaxial structure 130 and the first semiconductor layer 151 of the third epitaxial structure 150.

Each of the first junction layer 120 and the second junction layer 140 may include, for example, a group III-V compound semiconductor based on GaN, like the first epitaxial structure 110, the second epitaxial structure 130 and the third epitaxial structure 150. For example, the first junction layer 120 and the second junction layer 140 may include a group III-V compound semiconductor such as GaN, InGaN, AlInGaN, AlGaInP and the like. For example, the first junction layer 120 and the second junction layer 140 may include GaN. In addition, the first junction layer 120 forms a tunnel junction with the second semiconductor layer 117 of the first epitaxial structure 110 and may be doped with a doping concentration greater than the first semiconductor layer 131 in the same conductivity type as the first semiconductor layer 131 of the second epitaxial structure 130. The second junction layer 140 forms a tunnel junction with the second semiconductor layer 137 of the second epitaxial structure 130 and may be doped with the same conductivity type as the first semiconductor layer 151 of the third epitaxial structure 150 at a doping concentration greater than the first semiconductor layer 151.

In an example case in which the first semiconductor layer 131 of the second epitaxial structure 130 and the first semiconductor layer 151 of the third epitaxial structure 150 are doped with impurities of the n type, each of the first junction layer 120 and the second junction layer 140 may be doped with impurities of an n++ type. The n++ type doping may be obtained, for example, by setting the Si doping concentration to about 10¹⁹ or more. In this case, some thickness portions 131a and 151a of the first semiconductor layers 131 and 151 adjacent to the first and second junction layers 120 and 140, respectively, may have a doping concentration greater than the remaining thickness portions. In an example case in which the first semiconductor layers 131 and 151 are doped with impurities of the n type, the adjacent thickness portions 131a and 151a of the first semiconductor layers 131 and 151 may be formed in an n+ type and the remaining thickness portions of the first semiconductor layers 131 and 151 may be formed in the n type. For example, the first junction layer 120 and the second junction layer 140 may be formed of GaN of the n++ type, adjacent thickness portions 131a and 151a of the first semiconductor layers 131 and 151 may be formed of GaN of the n+ type and the remaining thickness portions of the first semiconductor layers 131 and 151 may be formed of GaN of the n type. In another example case in which the first semiconductor layers 131 and 151 are doped with impurities of the p type, the first and second junction layers 120 and 140 may be doped with impurities of a p++ type. In this case, some thickness portions 131a and 151a of the first semiconductor layers 131 and 151 adjacent to the first and second junction layers 120 and 140, respectively, may have a doping concentration greater than the remaining thickness portions. In an example case in which the first semiconductor layers 131 and 151 are doped with impurities of the p type, the adjacent thickness portions 131a and 151a of the first semiconductor layers 131 and 151 may be formed in a p+ type and the remaining thickness portions of the first semiconductor layers 131 and 151 may be formed in the p type.

In an example case in which doping concentrations of the first and second junction layers 120 and 140, the adjacent thickness portions 131a and 151a and the remaining thickness portions of the first semiconductor layer 131 and 151 are referred to as a first doping concentration, a second doping concentration and a third doping concentration, respectively, the first and second junction layers 120 and 140 and the first semiconductor layer 131 and 151 may be formed to satisfy the relationship where the first doping concentration>the second doping concentration>the third doping concentration.

According to an embodiment, in the first to third epitaxial structures 110, 130 and 150, the first semiconductor layers 111, 131 and 151 include n-GaN, the first carrier blocking layers 113, 133 and 153 include AlInGaN as HBLs, the second carrier blocking layers 116, 136 and 156 include p-AlGaN as EBLs, the second semiconductor layers 117, 137 and 157 include p-GaN and the first junction layer 120 and the second junction layer 140 may include GaN of the n++ type. In the first epitaxial structure 110, the second epitaxial structure 130 and the third epitaxial structure 150, the active layers 115, 135 and 155 may have a first barrier-single-quantum well or a multi-quantum well-second barrier stack structure. The first barrier may include GaN, in which Si may or may not be doped. The second barrier may include GaN, e.g., intrinsic GaN. The quantum well may include a single stack structure or a multiple stack structure of InGaN/GaN or InGaN/GaN/AlGaN and the composition ratio of In and Ga in InₓGa₁₋ₓN may vary depending on the emission wavelength and GaN may or may not be doped with Si. In an example case in which the first epitaxial structure 110, the second epitaxial structure 130 and the third epitaxial structure 150 generate blue light, green light and red light, respectively, the active layer 135 of the second epitaxial structure 130 and the active layer 155 of the third epitaxial structure 150 may or may not include an AlGaN layer and the active layer 115 of the first epitaxial structure 110 may not include AlGaN. In the first epitaxial structure 110, the second epitaxial structure 130 and the third epitaxial structure 150, an x value at InₓGa₁₋ₓN of the active layers 115, 135 and 155 may vary according to a light emission wavelength, as described above.

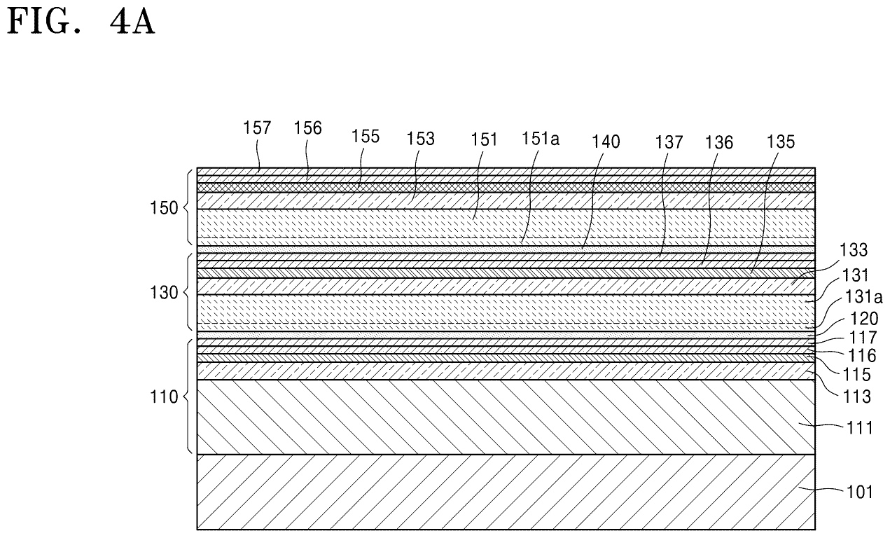

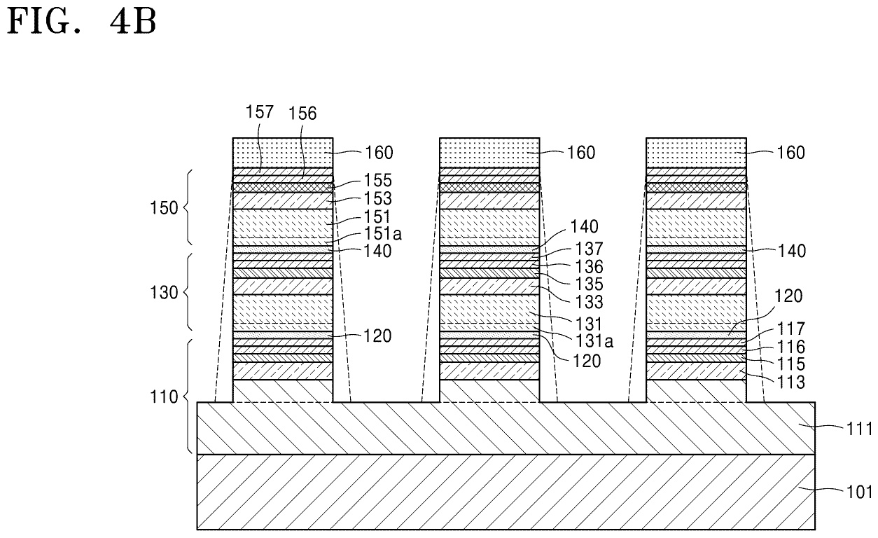

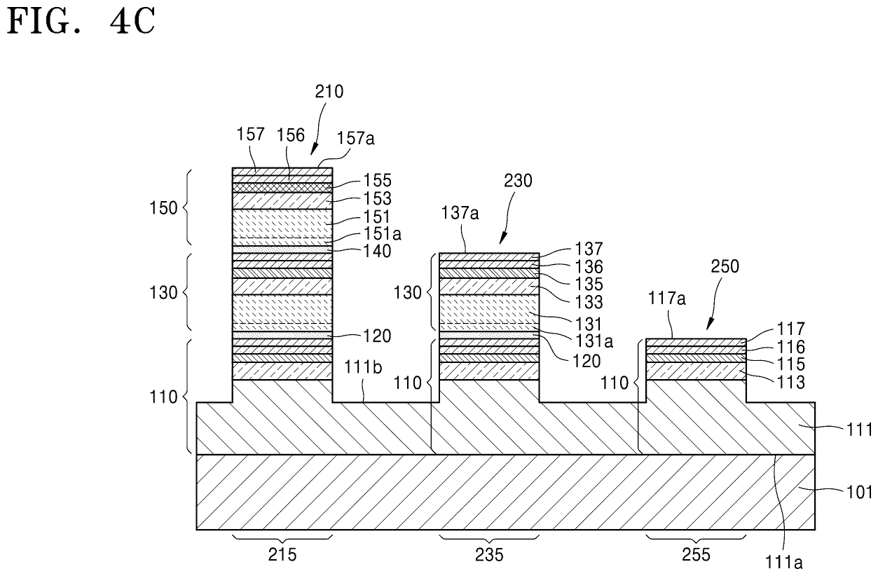

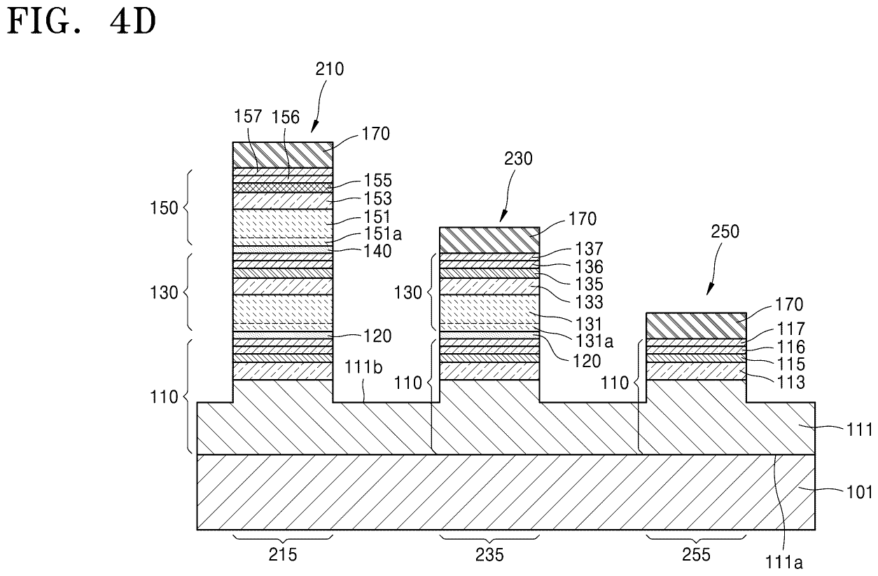

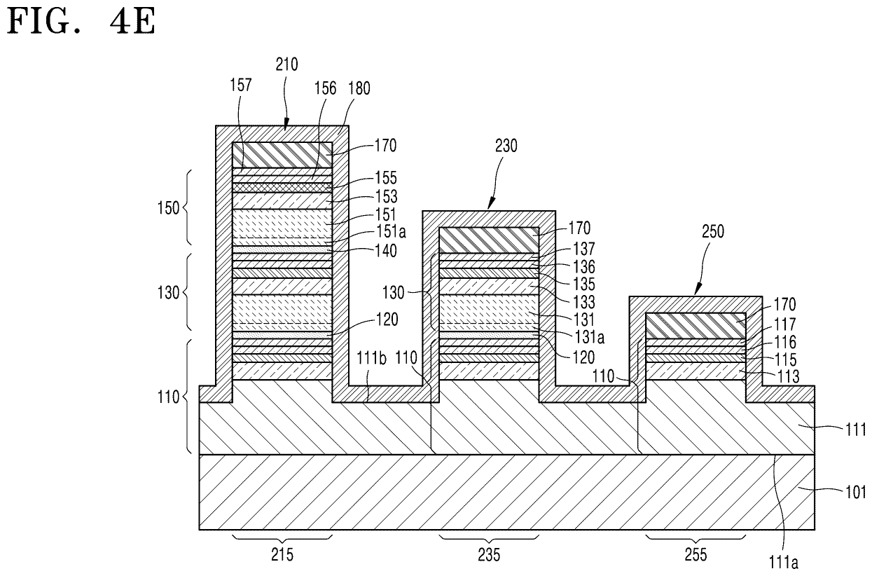

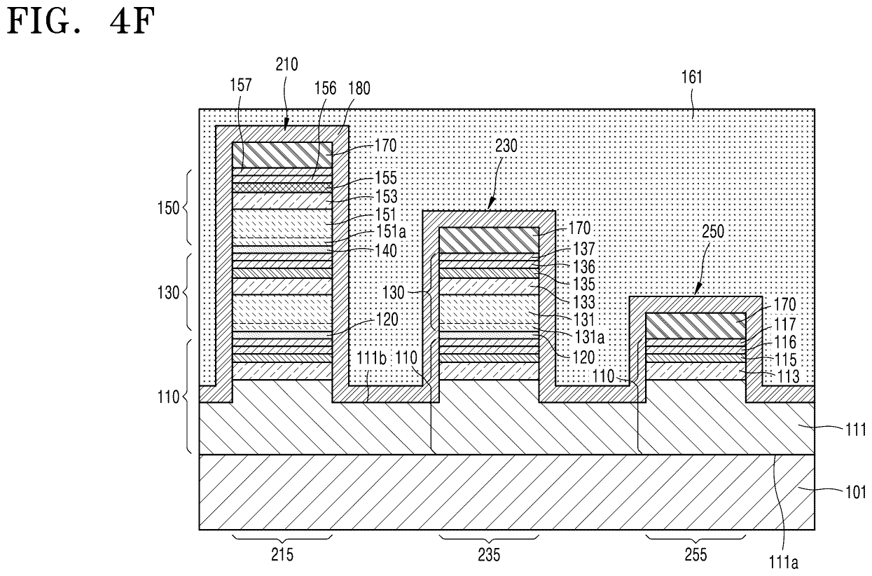

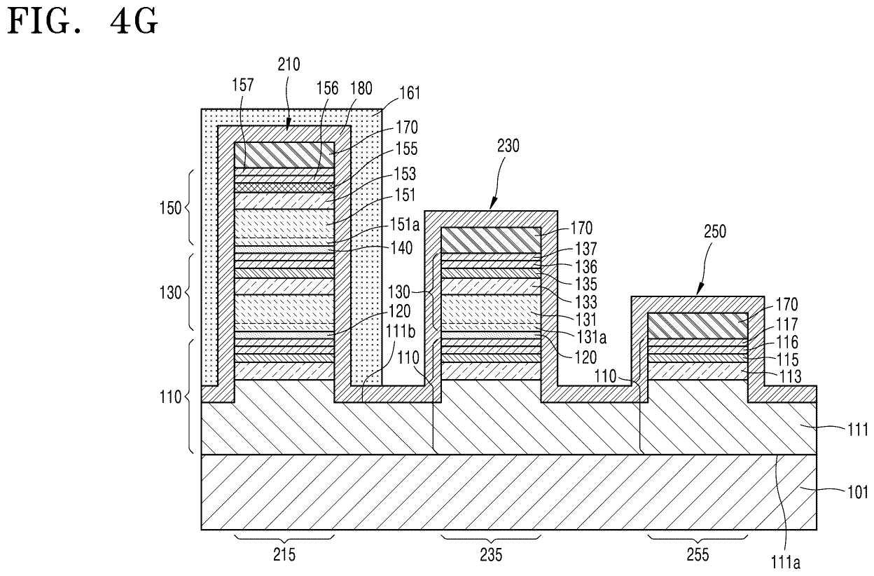

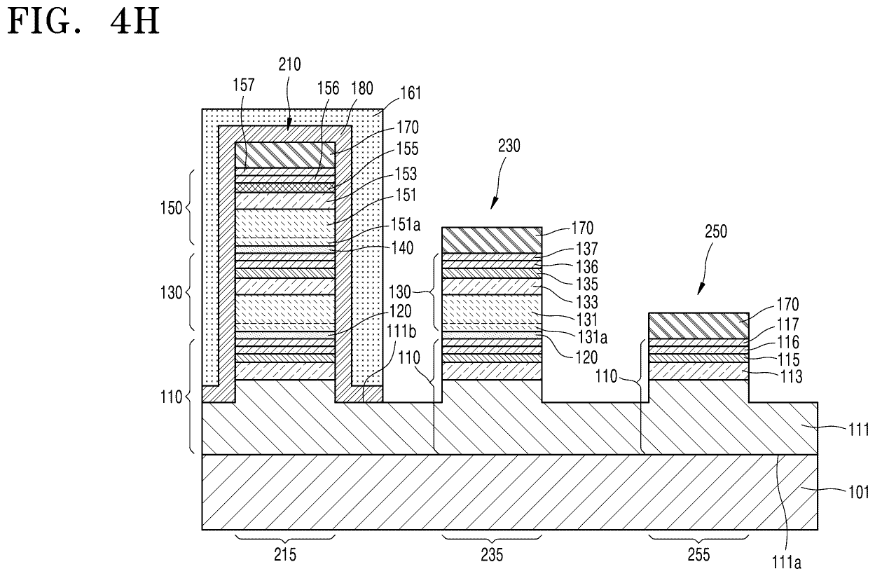

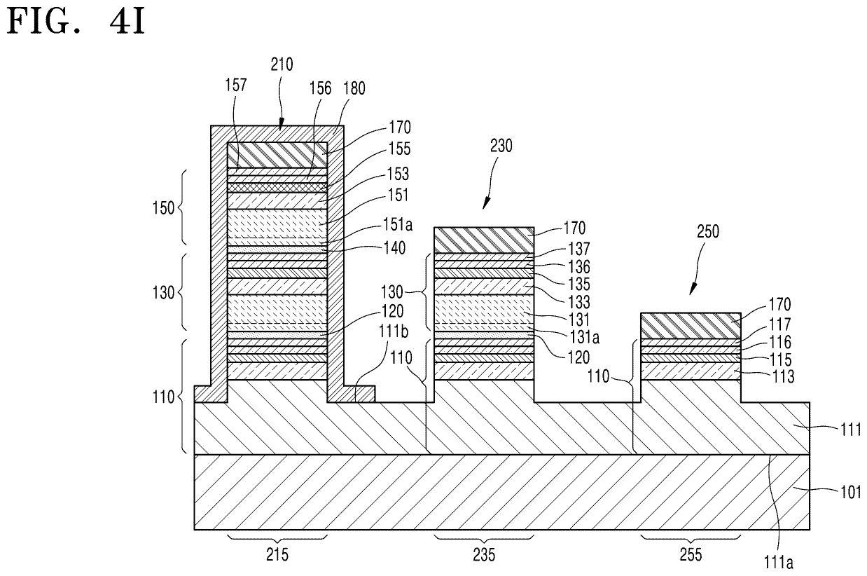

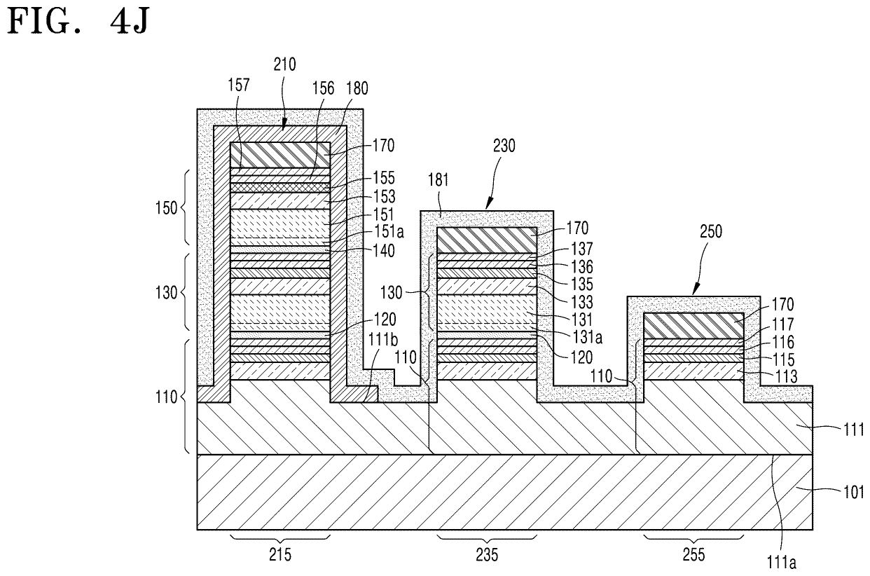

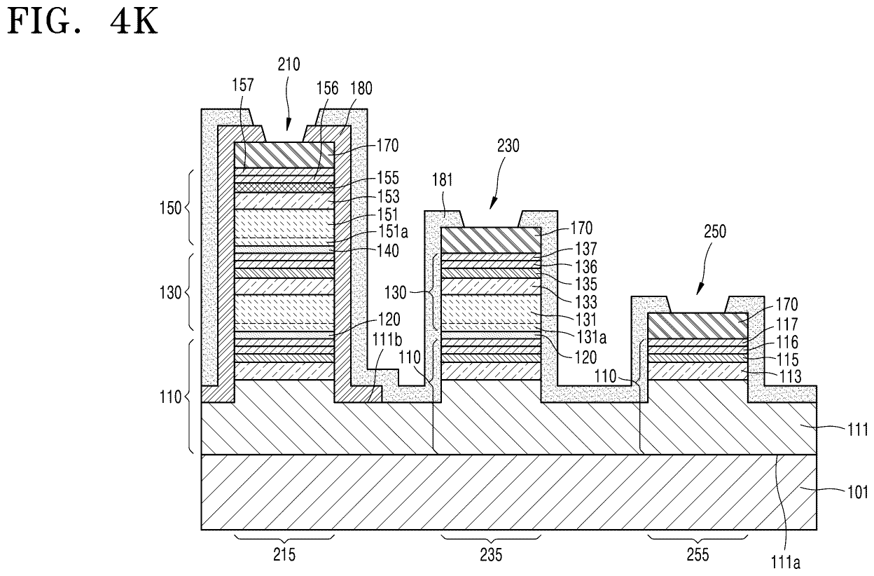

The first mesa structure 210, the second mesa structure 230 and the third mesa structure 250 may be formed by a selective etching process of the first epitaxial structure 110, the second epitaxial structure 130 and the third epitaxial structure 150. The selective etching process will be described later with reference to FIG. 4C.

The first mesa structure 210 includes the third epitaxial structure 150 on an uppermost portion of which the second semiconductor layer 157 is exposed. The second mesa structure 230 includes the second epitaxial structure 130 on an uppermost portion of which the second semiconductor layer 137 is exposed. The third mesa structure 250 includes the first epitaxial structure 110 on an uppermost portion of which the second semiconductor layer 117 is exposed. In addition, an exposed surface 111b formed by etching the thickness of the first semiconductor layer 111 of the first epitaxial structure 110 is etched is located in a region among the first mesa structure 210, the second mesa structure 230 and the third mesa structure 250.

The heights of the first mesa structure 210, the second mesa structure 230 and the third mesa structure 250 formed by the selective etching process may correspond to, for example, thicknesses from the exposed surface 111b formed by etching a part of the thickness of the first semiconductor layer 111 of the first epitaxial structure 110 to the top surfaces of the second semiconductor layers of the epitaxial structures located at the uppermost portions of the respective mesa structures.

That is, the first mesa structure 210 has a height ranging from the etched exposed surface 111b of the first semiconductor layer 111 of the first epitaxial structure 110 to a top surface 157a of the second semiconductor layer 157 of the third epitaxial structure 150, the second mesa structure 230 has a height ranging from the etched exposed surface 111b of the first semiconductor layer 111 to a top surface 137a of the second semiconductor layer 137 of the second epitaxial structure 130 and the third mesa structure 250 has a height ranging from the etched exposed surface 111b of the first semiconductor layer 111 to a top surface 117a of the second semiconductor layer 117.

In this manner, the first mesa structure 210, the second mesa structure 230 and the third mesa structure 250 having different heights may be formed by a selective etching process for a plurality of mesa structures and The first mesa structure 210, the second mesa structure 230 and the third mesa structure 250 form a first light emitting element 215, a second light emitting element 235 and a third light emitting element 255 that emit different wavelengths corresponding to the generation wavelengths of the active layer 115 of the third epitaxial structure 150, the active layer 135 of the second epitaxial structure 130 and the active layer 115 of the first epitaxial structure 110, which are located at uppermost portions thereof, respectively.

In the first mesa structure 210, the movement of carriers (e.g., holes) from the second semiconductor layer 157 of the third epitaxial structure 150 toward the first semiconductor layer 151 is blocked by the first carrier blocking layer 153, so carriers (e.g., holes) are not transferred from the third epitaxial structure to the first epitaxial structure 110 and the second epitaxial structure 130 located below. The first mesa structure 210 forms a first color light emitting region, for example, a red light emitting region, by the third epitaxial structure 150, thereby forming a first light emitting element 215 that emits red light.

In the second mesa structure 230, the movement of carriers (e.g., holes) from the second semiconductor layer 137 of the second epitaxial structure 130 toward the first semiconductor layer 131 is blocked by the first carrier blocking layer 133, so carriers (e.g., holes) are not transmitted from the second epitaxial structure 130 to the first epitaxial structure 110 located below. Accordingly, the second mesa structure 230 forms a second color light emitting region, e.g., a green light emitting region by the second epitaxial structure 130, thereby forming a second light emitting element 235 that emits green light.

The third mesa structure 250 forms a third color light emitting region, for example, a blue light emitting region, by the first epitaxial structure 110, thereby forming a third light emitting element 255 that emits blue light.

In this manner, the first light emitting element 215, the second light emitting element 235 and the third light emitting element 255 that emit light of different wavelengths may be formed. That is, the first light emitting element 215, the second light emitting element 235 and the third light emitting element 255 that emit first to third color light, respectively, may be formed.

Since the first color light emitting region formed by the first mesa structure 210, the second color light emitting region formed by the second mesa structure 230 and the third color light emitting region, formed by the third mesa structure 250 are spaced apart from each other, the first light emitting element 215, the second light emitting element 235 and the third light emitting element 255 are spaced apart from each other. However, the first light emitting element 215, the second light emitting element 235 and the third light emitting element 255 are connected through a portion of the first semiconductor layer 111 of the first epitaxial structure 110, and as such, the first light emitting element 215, the second light emitting element 235 and the third light emitting element 255 may be formed in a monolithic form. For example, the first light emitting element 215, the second light emitting element 235 and the third light emitting element 255 may share at least a partial thickness portion of the first semiconductor layer 111 of the first epitaxial structure 110.

A first electrode 170 may be arranged on each of the second semiconductor layer 157 of the third epitaxial structure 150 of the first mesa structure 210, the second semiconductor layer 137 of the second epitaxial structure 130 of the second mesa structure 230 and the second semiconductor layer 117 of the first epitaxial structure 110 of the third mesa structure 250. The first electrode 170 may be a transparent electrode formed on the surfaces of the second semiconductor layers 157, 137 and 117. The first electrode 170 may be, for example, an indium tin oxide (ITO) electrode.

FIG. 1 shows that the first light emitting element 215, the second light emitting element 235 and the third light emitting element 255 are arranged side by side, but the embodiments are not limited thereto and the arrangement method of the first light emitting element 215, the second light emitting element 235 and the third light emitting element 255 may vary depending upon a scheme of implementing the color pattern of the display device 1000. In addition, each of the first light emitting element 215, the second light emitting element 235 and the third light emitting element 255 that emit different colors may correspond to a sub-pixel of the display device 1000 and a unit pixel of the display device 1000 may include three or more sub-pixels. Therefore, the display device 1000 according to an embodiment may include at least one of each of the first light emitting element 215, the second light emitting element 235 and the third light emitting element 255 in a unit pixel.

A first passivation layer 180 may be arranged to surround a sidewall of the first light emitting element 215. The first passivation layer 180 may be arranged to cover a portion of the exposed surface 111b of the first semiconductor layer 111 of the first epitaxial structure 110. The first light emitting element 215 includes the first passivation layer 180 on a sidewall of the first light emitting element 215, thereby increasing light emission efficiency. In addition to increasing the emission efficiency of the first light emitting element 215, the first passivation layer 180 may serve to protect the first light emitting element 215 from external physical and chemical impact and to insulate the first light emitting element 215 to prevent leakage of current.

The thickness of the first passivation layer 180 may have, for example, a range of about 10 nm to about 30 nm. However, the disclosure is not limited thereto, and as such, according to another embodiment, the thickness of the first passivation layer 180 may have, for example, a range of about 5 nm to about 50 nm.

The first light emitting element 215 may emit red light and the first passivation layer 180 may include AlOₓN_{y}. The first light emitting element 215 includes the first passivation layer 180 including AlOₓN_{y} to increase light emission efficiency of red light having a peak wavelength in the range of about 610 nm to about 650 nm.

The second passivation layer 181 may be arranged to surround the sidewalls of the second light emitting element 235 and the third light emitting element 255. The second passivation layer 181 may be provided on sidewalls of the second light emitting element 235 and the third light emitting element 255 to increase light emission efficiency of the second light emitting element 235 and the third light emitting element 255. The second passivation layer 181 may serve to protect the second light emitting element 235 and the third light emitting element 255 from external physical and chemical impacts and to insulate the second light emitting element 235 and the third light emitting element 255 to prevent leakage of current.

The thickness of the second passivation layer 181 may have, for example, a range of about 10 nm to about 30 nm. However, the disclosure is not limited thereto, and as such, according to another embodiment, the thickness of the second passivation layer 181 may have, for example, a range of about 5 nm to about 50 nm. The second passivation layer 181 may include a single layer or a plurality of layers. The second passivation layer 181 may include, for example, 1 to 5 layers.

The third light emitting element 255 may emit blue light and the second passivation layer 181 may include Ta₂O₅. The third light emitting element 255 may include the second passivation layer 181 including tantalum oxide to increase light emission efficiency of blue light having a peak wavelength in the range of about 430 nm to about 470 nm. The second passivation layer 181 may include, for example, Ta₂O₅.

The second passivation layer 181 may be arranged to surround a sidewall of the first passivation layer 180. The second passivation layer 181 may be formed after the first passivation layer 180 during the manufacturing process and may be arranged to surround the sidewall of the first passivation layer 180.

According to an embodiment of the disclosure, the display device 1000 may increase the efficiency of the light emitting element by applying different passivation layers to the first light emitting element 215 and the third light emitting element 255. That is, it is possible to increase the efficiency of the light emitting element by applying the first passivation layer 180 including AlOₓN_{y} to the first light emitting element 215 that emits red light and the second passivation layer 181 including tantalum oxide to the third light emitting element 255 that emits blue light.

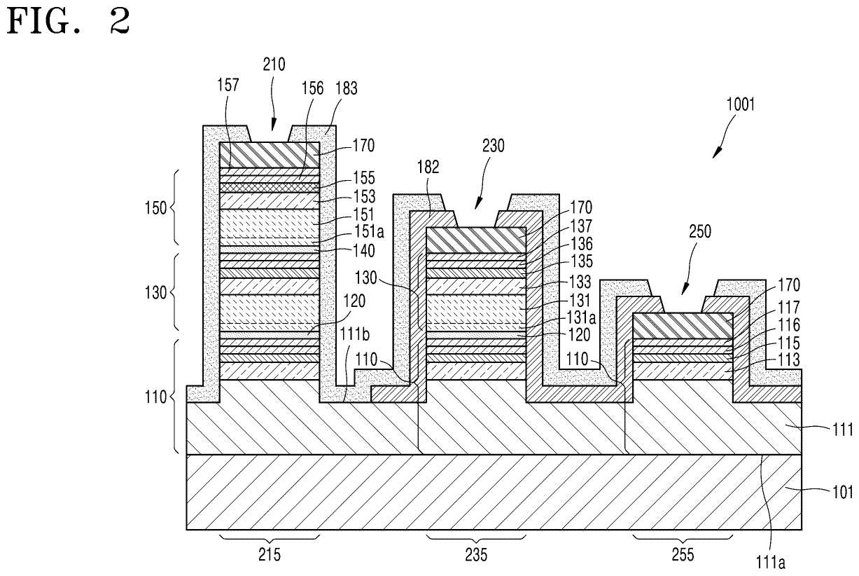

FIG. 2 is a cross-sectional view illustrating a display device according to an embodiment.

Referring to FIG. 2, a display device 1001 may include a first light emitting element 215 including a first epitaxial structure 110, a second epitaxial structure 130 and a third epitaxial structure 150, which are vertically stacked on a substrate 101, a third light emitting element 255 spaced apart from the first light emitting element 215 and including the first epitaxial structure 110, a first passivation layer 182 arranged to surround a sidewall of the third light emitting element 255 and a second passivation layer 183 arranged to surround a sidewall of the first light emitting element 215.

The display device 1001 of FIG. 2 may be the same as the display device 1000 of FIG. 1, except that the second passivation layer 183 surrounds the sidewall of the first light emitting element 215 and the first passivation layer 182 surrounds the sidewall of the second light emitting element 235 and the sidewall of the third light emitting element 255. In describing FIG. 2, redundant descriptions of FIG. 1 are omitted.

The first light emitting element 215 includes the second passivation layer 183 on the sidewall of the first light emitting element 215, thereby increasing light emission efficiency. In addition to increasing the emission efficiency of the first light emitting element 215, the second passivation layer 183 may serve to protect the first light emitting element 215 from external physical and chemical impact and to insulate the first light emitting element 215 to prevent leakage of current.

The thickness of the second passivation layer 183 may have, for example, a range of about 10 nm to about 30 nm. However, the disclosure is not limited thereto, and as such, according to another embodiment, the thickness of the second passivation layer 183 may have, for example, a range of about 5 nm to about 50 nm.

The first light emitting element 215 may emit red light and the second passivation layer 183 may include AlOₓN_{y}. The first light emitting element 215 includes the second passivation layer 183 including AlOₓN_{y} to increase light emission efficiency of red light having a peak wavelength in the range of about 610 nm to about 650 nm.

The first passivation layer 182 may be arranged to surround the sidewalls of the second light emitting element 235 and the third light emitting element 255. The first passivation layer 182 may be provided on sidewalls of the second light emitting element 235 and the third light emitting element 255 to increase light emission efficiency of the second light emitting element 235 and the third light emitting element 255. The first passivation layer 182 may serve to protect the second light emitting element 235 and the third light emitting element 255 from external physical and chemical impacts and to insulate the second light emitting element 235 and the third light emitting element 255 to prevent leakage of current.

The thickness of the first passivation layer 182 may have, for example, a range of about 10 nm to about 30 nm. However, the disclosure is not limited thereto, and as such, according to another embodiment, the thickness of the first passivation layer 182 may have, for example, a range of about 5 nm to about 50 nm. The first passivation layer 182 may include a single layer or a plurality of layers. The first passivation layer 182 may include, for example, 1 to 5 layers.

The third light emitting element 255 may emit blue light and the second passivation layer 182 may include Ta₂O₅. The third light emitting element 255 may include the first passivation layer 182 including tantalum oxide to increase light emission efficiency of blue light having a peak wavelength in the range of about 430 nm to about 470 nm. The first passivation layer 182 may include, for example, Ta₂O₅.

The second passivation layer 183 may be arranged to surround a sidewall of the first passivation layer 182. The second passivation layer 183 may be formed after the first passivation layer 182 during the manufacturing process and may be arranged to surround the sidewall of the first passivation layer 182.

According to an embodiment of the disclosure, the display device 1001 may increase the efficiency of the light emitting element by applying different passivation layers to the first light emitting element 215 and the third light emitting element 255.

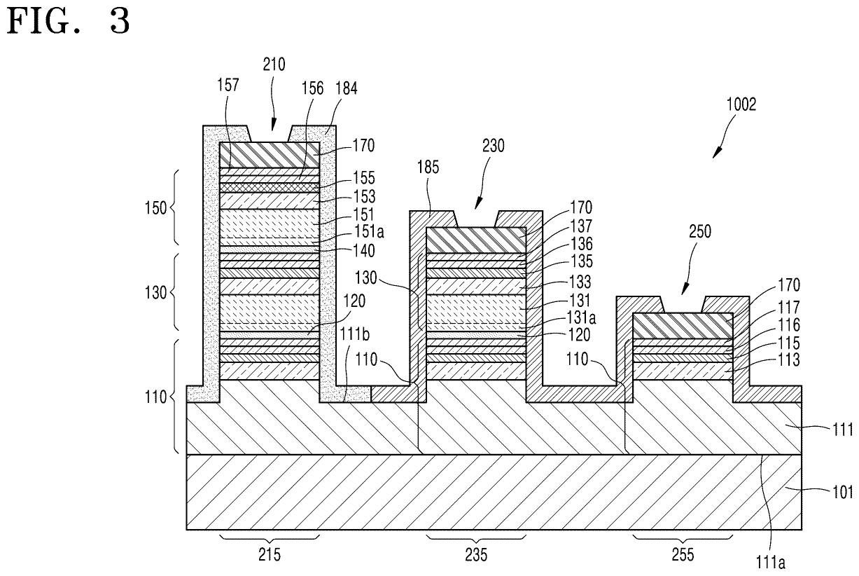

FIG. 3 is a cross-sectional view illustrating a display device according to an embodiment.

Referring to FIG. 3, a display device 1002 may include a first light emitting element 215 including a first epitaxial structure 110, a second epitaxial structure 130 and a third epitaxial structure 150, which are vertically stacked on a substrate 101, a third light emitting element 255 spaced apart from the first light emitting element 215 and including the first epitaxial structure 110, a first passivation layer 184 arranged to surround a sidewall of the first light emitting element 215 and a second passivation layer 185 arranged to surround a sidewall of the third light emitting element 255.

The display device 1002 of FIG. 3 may be the same as the display device 1000 of FIG. 1, except that the second passivation layer 185 does not surround the first passivation layer 184 surrounding the sidewall of the first light emitting element 215. In describing FIG. 3, redundant descriptions of FIG. 1 are omitted.

The first passivation layer 184 may be arranged to surround a sidewall of the first light emitting element 215. The first light emitting element 215 includes the first passivation layer 184 on a sidewall of the first light emitting element 215, thereby increasing light emission efficiency.

The first light emitting element 215 may emit red light and the first passivation layer 184 may include AlOₓN_{y}. The first light emitting element 215 includes the first passivation layer 184 including AlOₓN_{y} to increase light emission efficiency of red light having a peak wavelength in the range of about 610 nm to about 650 nm.

The second passivation layer 185 may be arranged to surround the sidewalls of the second light emitting element 235 and the third light emitting element 255. The second passivation layer 185 may be provided on sidewalls of the second light emitting element 235 and the third light emitting element 255 to increase light emission efficiency of the second light emitting element 235 and the third light emitting element 255. The second passivation layer 185 may serve to protect the second light emitting element 235 and the third light emitting element 255 from external physical and chemical impacts and to insulate the second light emitting element 235 and the third light emitting element 255 to prevent leakage of current.

The third light emitting element 255 may emit blue light and the second passivation layer 185 may include Ta₂O₅. The third light emitting element 255 may include the second passivation layer 185 including tantalum oxide to increase light emission efficiency of blue light having a peak wavelength in the range of about 430 nm to about 470 nm. The second passivation layer 185 may include, for example, Ta₂O₅.

According to an embodiment, the display device 1002 may increase the efficiency of the light emitting element by applying different passivation layers to the first light emitting element 215 and the third light emitting element 255.

FIGS. 4A to 4K are cross-sectional views illustrating a method of manufacturing a display device according to an embodiment.

Referring to FIG. 4A, a vertical stacked epitaxial structure is formed by sequentially stacking a first epitaxial structure 110, a second epitaxial structure 130 and a third epitaxial structure 150 on a substrate 101.

In order to form the first epitaxial structure 110, the first semiconductor layer 111 is formed on the substrate 101, the first carrier blocking layer 113 is formed on the first semiconductor layer 111, the active layer 115 for the first color light emission is formed on the first carrier blocking layer 113, the second carrier blocking layer 116 is formed on the active layer 115 and the second semiconductor layer 117 is formed on the second carrier blocking layer 116. The first color light may be blue light. However, the disclosure is not limited thereto, and as such, in an example case in which the buffer layer is provided between the substrate 101 and the first epitaxial structure 110, the first semiconductor layer 111 may be formed on the buffer layer.

In order to form the second epitaxial structure 130, the first semiconductor layer 131 is formed on the second semiconductor layer 117 of the first epitaxial structure 110, the first carrier blocking layer 133 is formed on the first semiconductor layer 131, the active layer 135 for second color light emission is formed on the first carrier blocking layer 133, the second carrier blocking layer 136 is formed on the active layer 135 and the second semiconductor layer 137 is formed on the second carrier blocking layer 136. The second color light may be green light.

In order to form the third epitaxial structure 150, the first semiconductor layer 151 is formed on the second semiconductor layer 137 of the second epitaxial structure 130, the first carrier blocking layer 153 is formed on the first semiconductor layer 151, the active layer 155 for third color light emission is formed on the first carrier blocking layer 153, the second carrier blocking layer 156 is formed on the active layer 155 and the second semiconductor layer 157 is formed on the second carrier blocking layer 156. The third color light may be red light.

Referring to FIG. 4B, a mask pattern 160 is formed on a vertically stacked epitaxial structure of the first epitaxial structure 110, the second epitaxial structure 130 and the third epitaxial structure 150 and a region other than the light emitting region is etched to a partial depth of a portion of the first semiconductor layer 111 of the first epitaxial structure 110, thereby forming a plurality of mesa structures. According to an embodiment, the plurality of mesa structures may be formed in an array.

The mask pattern 160 for forming a plurality of mesa structures may include, for example, an SiO₂ hard mask. The plurality of mesa structure arrays may be formed by etching regions not covered with the mask pattern 160 to a partial depth of a portion of the first semiconductor layer 111 of the first epitaxial structure 110 through a dry etching process. In this case, since the mesa structures formed by the dry etching process have inclined sidewalls (represented by dotted lines in FIG. 4B), a wet etching process may be additionally performed to increase the inclination of the inclined sidewalls. By increasing the slopes of the inclined sidewalls of the mesa structures through the wet etching process, the mesa structures may be made relatively constant in width. In FIG. 4B, dotted line profiles represent the mesa structures formed by the dry etching process. The dry etching process may use, for example, inductively coupled plasma (ICP). The wet etching process may be performed using, for example, a potassium hydroxide (KOH) solution or a tetramethylammonium hydroxide (TMAH) solution as an etching solution. The widths of the mesa structures formed in this manner may be relatively constant. The width of each of the mesa structures may be in a range of, for example, about 0.1 μm to about 100 μm. Accordingly, as described later, a light emitting element formed corresponding to a mesa structure may form a micro light emitting element.

Referring to FIG. 4C, some of the plurality of mesa structures are etched to form the first mesa structure 210 including the first epitaxial structure 110, the second epitaxial structure 130 and the third epitaxial structure 150, the second mesa structure 230 including the first epitaxial structure 110 and the second epitaxial structure 130 and the second mesa structure 250 including the first epitaxial structure 110.

For example, the etching process is not performed on the first mesa structure 210. However, in order to form the second mesa structure 230, an etching process is performed to remove the third epitaxial structure 150 located at the uppermost end and the second junction layer 140. Moreover, in order to form the third mesa structure 250, an etching process of removing the third epitaxial structure 150, the second junction layer 140, the second epitaxial structure 130 and the first junction layer 120 is performed. The first mesa structure 210, the second mesa structure 230 and the third mesa structure 250 may have different heights by a selective etching process.

Referring to FIG. 4D, an electrode 170 is formed on the first mesa structure 210, the second mesa structure 230 and the third mesa structure 250. The electrode 170 may be formed to be in contact with the uppermost second semiconductor layers 157, 137 and 117 of the first mesa structure 210, the second mesa structure 230 and the third mesa structure 250. The electrode 170 may be a transparent electrode, for example, an ITO electrode.

Referring to FIG. 4E, the first passivation layer 180 is formed on the first mesa structure 210, the second mesa structure 230 and the third mesa structure 250. For example, the first passivation layer 180 may be deposited to surround sidewalls of the first mesa structure 210, the second mesa structure 230 and the third mesa structure 250. The first mesa structure 210 may form the first light emitting element 215 that emits red light and the first passivation layer 180 may include AlOₓN_{y}.

Referring to FIG. 4F, a mask 161 is formed on the first passivation layer 180. The mask 161 may be arranged to cover the entire first passivation layer 180.

Referring to FIG. 4G, a portion of the mask 161 is removed through an exposure process to expose a portion of the first passivation layer 180 surrounding the sidewalls of the second mesa structure 230 and the third mesa structure 250.

Referring to FIGS. 4H and 4I, a portion of the first passivation layer 180, which is not covered with the mask 161, is removed through a dry etching process and then the remaining mask 161 is removed.

Referring to FIG. 4J, the second passivation layer 181 may be formed on the second mesa structure 230 and the third mesa structure 250. For example, the second passivation layer 181 may be deposited to surround the second mesa structure 230 and the third mesa structure 250. According to an embodiment, the second passivation layer 181 may be formed on the first passivation layer 180. For example, the second passivation layer 181 may be deposited to surround a sidewall of the first passivation layer 180. The second mesa structure 230 may form the second light emitting element 235 emitting green light, the third mesa structure 250 may form the third light emitting element 255 emitting blue light and the second passivation layer 181 may include tantalum oxide.

Referring to FIG. 4K, some portions of the first passivation layer 180 and the second passivation layer 181 are etched to expose at least some portions of the electrode 170 on the first mesa structure 210, the second mesa structure 230 and the third mesa structure 250.

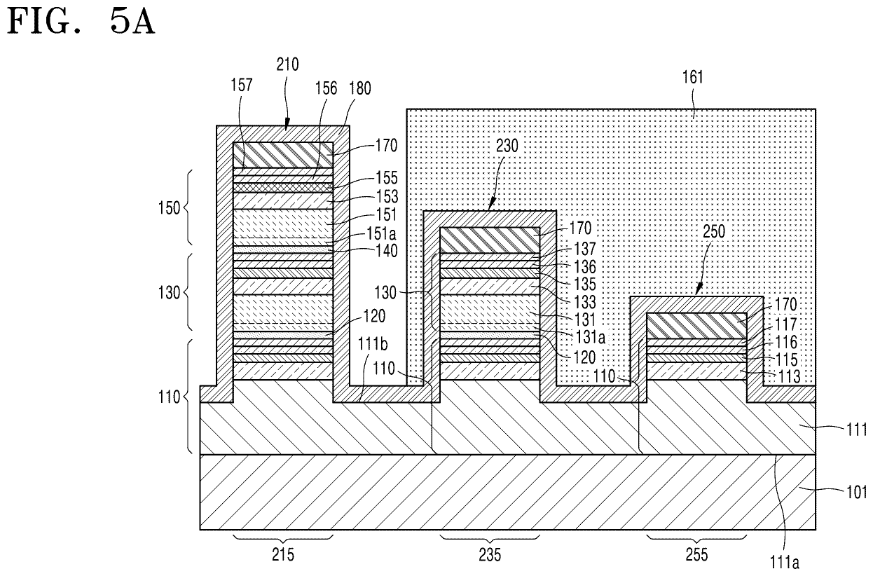

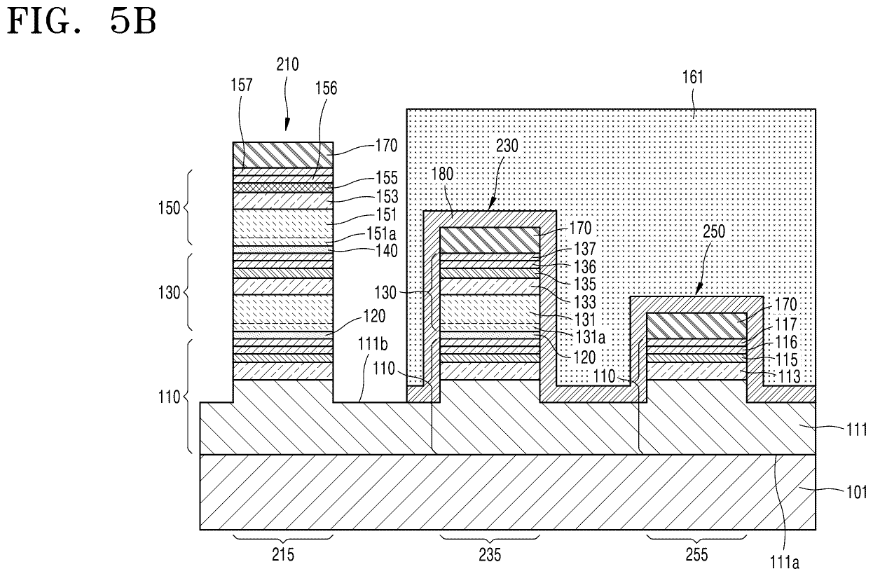

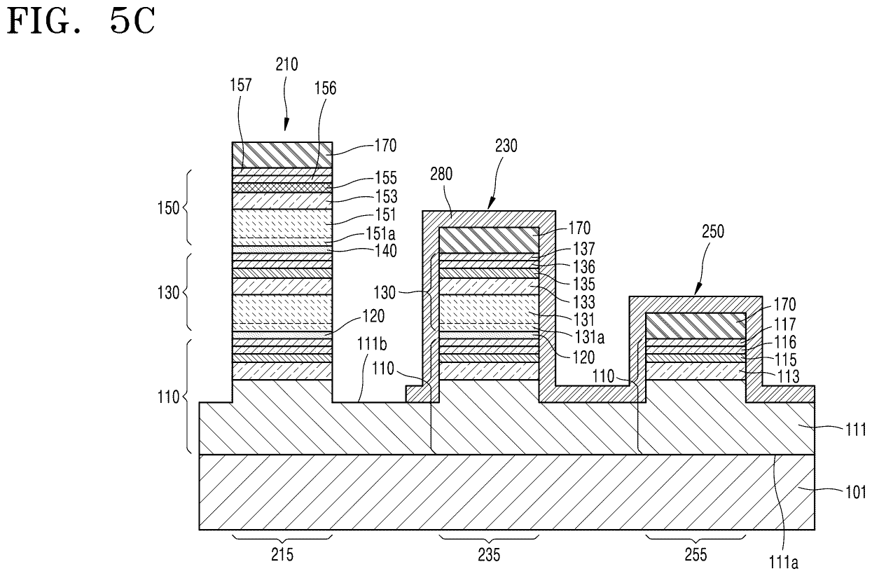

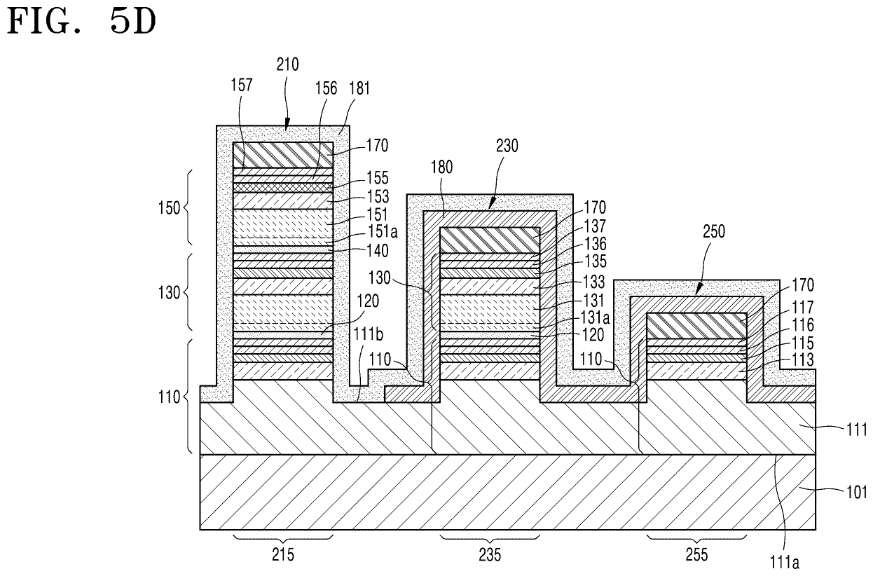

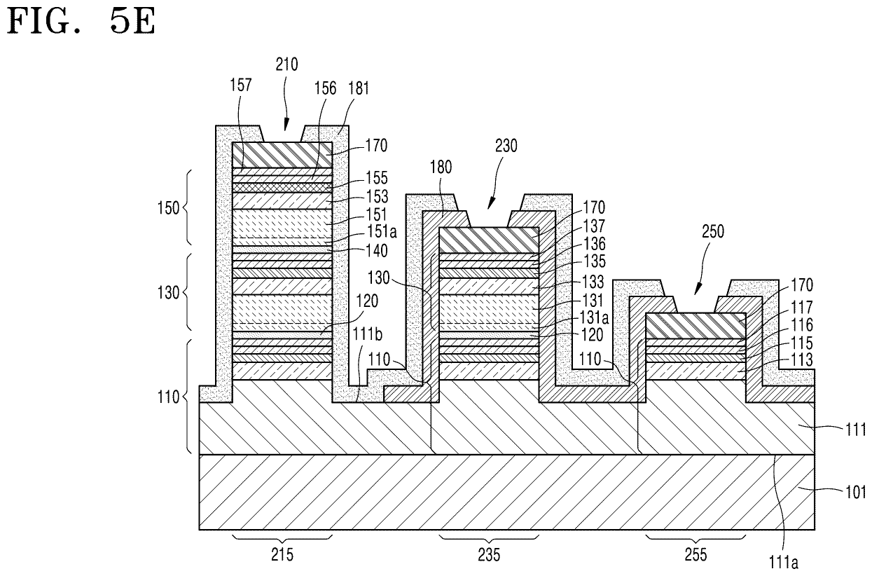

FIGS. 5A to 5E are cross-sectional views partially illustrating a method of manufacturing a display device according to an embodiment. Before the processes of FIGS. 5A to 5E, the processes of FIGS. 4A to 4F may be performed.

Referring to FIG. 5A, a portion of the mask 161 is removed through an exposure process. A portion of the first passivation layer 180 surrounding the sidewall of the first mesa structure 210 may be exposed and the mask 161 may be formed only on a portion of the first passivation layer 180 surrounding the sidewalls of the second mesa structure 230 and the third mesa structure 250. The second mesa structure 210 may form the second light emitting element 235 emitting green light, the third mesa structure 250 may form the third light emitting element 255 emitting blue light and the first passivation layer 180 may include tantalum oxide.

Referring to FIGS. 5B and 5C, a portion of the first passivation layer 180, which is not covered with the mask 161, is removed through a dry etching process and then the remaining mask 161 is removed.

Referring to FIG. 5D, the second passivation layer 181 may be formed on the first mesa structure 210. For example, the second passivation layer 181 is deposited to surround the first mesa structure 210. Also, the second passivation layer 181 may be formed on the first passivation layer 180. For example, the second passivation layer 181 may be deposited to surround a sidewall of the first passivation layer 180.

Referring to FIG. 5E, some portions of the first passivation layer 180 and the second passivation layer 181 are etched to expose at least some portions of the electrode 170 on the first mesa structure 210, the second mesa structure 230 and the third mesa structure 250.

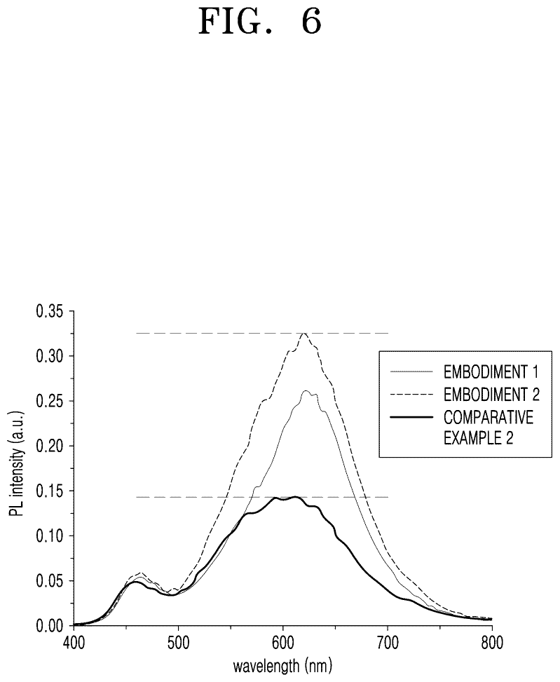

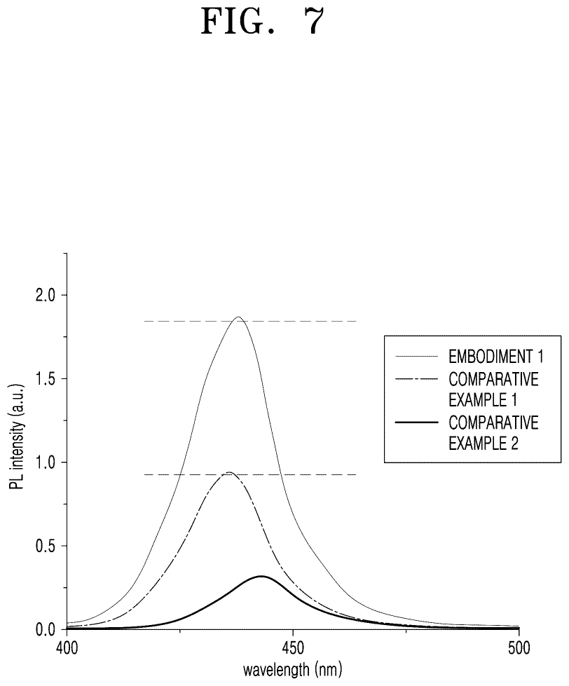

FIGS. 6 and 7 are graphs illustrating a change in photoluminescence (PL) intensity according to a wavelength of a light emitting element according to example embodiments 1 and 2 and a wavelength of a light emitting element according to a comparative examples 1 and 2. FIG. 6 shows the change in photoluminescence intensity according to the wavelength of the red light emitting element and FIG. 7 shows the change in photoluminescence intensity according to the wavelength of the blue light emitting element.

In example embodiment 1, a passivation layer including AlON and a passivation layer including TaO are sequentially applied to a light emitting element emitting red light and a passivation layer including TaO is applied to a light emitting element emitting blue light. In example embodiment 2, a passivation layer including AlON is applied to a light emitting element that emits red light and a passivation layer including TaO and a passivation layer including AlON are sequentially applied to a light emitting element that emits blue light. comparative example 1, a passivation layer including AlON and a passivation layer including TaO are sequentially applied to a light emitting element emitting red light and a light emitting element emitting blue light. In comparative example 2, a passivation layer including TaO and a passivation layer including AlON are sequentially applied to a light emitting element emitting red light and a light emitting element emitting blue light.

Referring to FIG. 6, the PL intensities of example embodiments 1 and 2 were relatively higher at a peak wavelength of about 620 nm than that of comparative example 2 and referring to FIG. 7, the PL intensity of example embodiment 1 was relatively higher at a peak wavelength of about 440 nm than those of comparative examples 1 and 2.

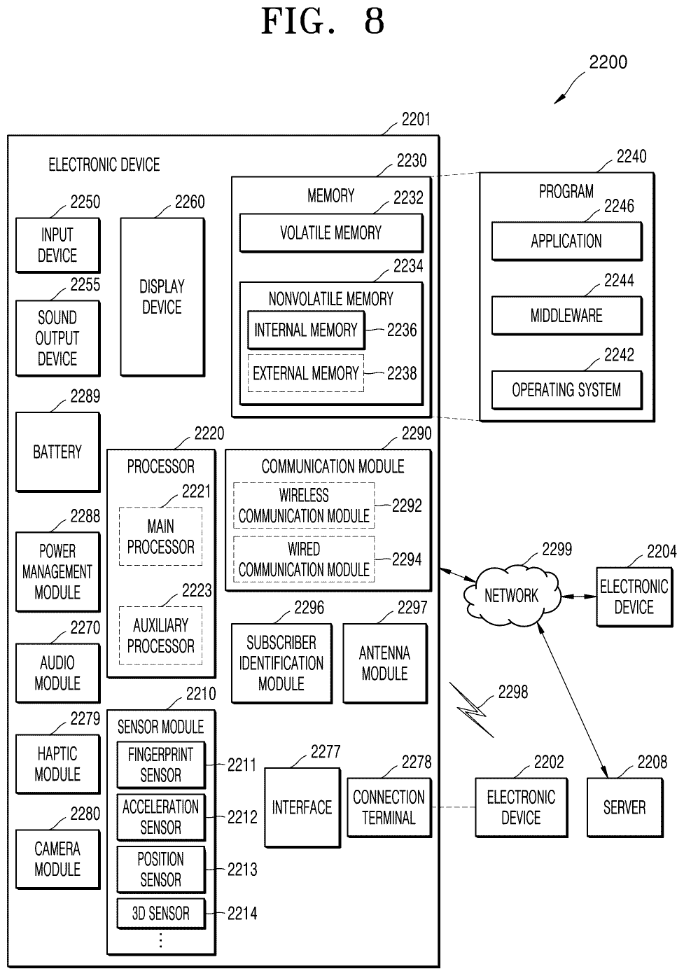

FIG. 8 is a block diagram illustrating a schematic configuration of an electronic device according to an embodiment.

Referring to FIG. 8, in a network environment 2200, an electronic device 2201 may communicate with another electronic device 2202 through a first network 2298 (a short-range wireless communication network or the like), or with another electronic device 2204 and/or a server 2208 through a second network 2299 (a long-range wireless communication network or the like). The electronic device 2201 may communicate with the electronic device 2204 through the server 2208. The electronic device 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296 and/or an antenna module 2297. Some of these components may be omitted from or other components may be added to the electronic device 2201. Some of these components may be implemented as one integrated circuit. For example, a fingerprint sensor, an iris sensor, an illuminance sensor, etc., of the sensor module 2210 may be implemented by being embedded in the display device 2260. In addition, each of the camera module 2280, the haptic module 2279 and the sensor module 2210 may include some parts of the processor 2220 and the memory 2230 therein.

The processor 2220 may execute software (program 2240 or the like) to control one or a plurality of other components (hardware and software components, or the like) of the electronic device 2201 connected to the processor 2220 and may perform processing or operations of various data. As part of data processing or operation, the processor 2220 may load commands and/or data received from other components (sensor modules 2210, communication modules 2290, etc.), process commands and/or data stored in volatile memory 2232 and store the result data in nonvolatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently of or together with the main processor 2221. The auxiliary processor 2223 may use less power than the main processor 2221 and perform a specialized function.

The auxiliary processor 2223 may control functions and/or states related to some (the display device 2260, sensor module 2210, communication module 2290, etc.) of the components of the electronic device 2201, in place of the main processor 2221 while the main processor 2221 is in an inactive state (slip state), or together with the main processor 2221 while the main processor 2221 is in an active state (application execution state). The auxiliary processor 2223 (image signal processor, communication processor, etc.) may be implemented as part of other functionally related components (camera module 2280, communication module 2290, etc.).

The memory 2230 may store various data required by components (processor 2220 and sensor module 2210) of the electronic device 2201. The data may include, for example, input data and/or output data for software (program 2240 or the like) and related commands. The memory 2230 may include a volatile memory 2232 and/or a nonvolatile memory 2234.

The program 2240 may be stored in the memory 2230 as software and may include an operating system 2242, middleware 2244 and/or an application 2246.

The input device 2250 may receive commands and/or data to be used in components (processor 2220, etc.) of the electronic device 2201 from the outside (user, etc.) of the electronic device 2201. The input device 2250 may include a microphone, a mouse, a keyboard and/or a digital pen (such as a stylus pen, etc.).

The sound output device 2255 may output the sound signal to the outside of the electronic device 2201. The sound output device 2255 may include a speaker and/or a receiver. Speakers may be used for general purposes such as multimedia playback or recording playback and receivers may be used to receive incoming calls. The receiver may be coupled as part of a speaker or may be implemented as an independent separate device.

The display device 2260 may visually provide information to the outside of the electronic device 2201. The display device 2260 may include the display device 100 according to an embodiment. The display device 2260 may include a display, a hologram device, or a projector and a control circuit for controlling the corresponding devices. The display device 2260 may include a touch circuitry configured to sense a touch and/or a sensor circuit (a pressure sensor, etc.) configured to measure an intensity of a force generated by the touch.

The audio module 2270 may convert sound into an electrical signal or conversely convert the electrical signal into sound. The audio module 2270 may acquire sound through the input device 2250 or output sound through the sound output device 2255 and/or a speaker and/or a headphone of another electronic device (e.g., electronic device 2202, etc.) directly or wirelessly connected to the electronic device 2201.

The sensor module 2210 may detect an operating state (power, temperature, etc.) or an external environmental state (user state, etc.) of the electronic device 2201 and generate an electrical signal and/or a data value corresponding to the sensed state. The sensor module 2210 may include a fingerprint sensor 2211, an acceleration sensor 2212, a position sensor 2213, a 3D sensor 2214 and in addition to this, may include an iris sensor, a gyro sensor, an atmospheric pressure sensor, a magnetic sensor, a grip sensor, a proximity sensor, a color sensor, an Infused (IR) sensor, a biometric sensor, a temperature sensor, a humidity sensor and/or an illuminance sensor.

The 3D sensor 2214 senses the shape and movement of an object by irradiating predetermined light to the object and analyzing the light reflected from the object and for example, an imaging optical system and an imaging device including the same may be applied.

The interface 2277 may support one or more designated protocols that may be used for electronic device 2201 to be directly or wirelessly connected to another electronic device (e.g., electronic device 2202, etc.). The interface 2277 may include a high definition multimedia interface (HDMI), a universal serial bus (USB) interface, a secure digital (SD) card interface and/or an audio interface.

The connection terminal 2278 may include a connector through which the electronic device 2201 may be physically connected to another electronic device (e.g., electronic device 2202, etc.). The connection terminal 2278 may include an HDMI connector, a USB connector, an SD card connector and/or an audio connector (such as a headphone connector, etc.).

The haptic module 2279 may convert an electrical signal to a mechanical stimulus (vibration, motion, etc.) or an electrical stimulus that a user can recognize through a tactile or motion sensation. The haptic module 2279 may include a motor, a piezoelectric element and/or an electrical stimulus.

The camera module 2280 may capture a still image and a moving image. The camera module 2280 may include an imaging optical system including one or more lenses, image sensors, image signal processors and/or flashes. The imaging optical system included in the camera module may collect light emitted from a subject that is a target of image capturing.

The power management module 2288 may manage power supplied to the electronic device 2201. The power management module 2288 may be implemented as part of a power management integrated circuit (PMIC).

The battery 2289 may supply power to components of the electronic device 2201. The battery 2289 may include a non-rechargeable primary battery, a rechargeable secondary battery and/or a fuel cell.

The communication module 2290 may establish a direct (wired) communication channel and/or wireless communication channel between the electronic device 2201 and another electronic device (the electronic device 2202, the electronic device 2204, the server 2208, etc.) and support communication execution through the established communication channel. The communication module 2290 may include one or more communication processors that operate independently of the processor 2220 (application processor, etc.) and support direct communication and/or wireless communication. The communication module 2290 may include a wireless communication module 2292 (a cellular communication module, a short-range wireless communication module, a GNSS (Global Navigation Satellite System, etc.) communication module and/or a wired communication module 2294 (a local area network (LAN) communication module, a power line communication module, etc.). A corresponding communication module of these communication modules may communicate with other electronic devices through a first network 2298 (a short-range communication network such as Bluetooth, WiFi Direct, or infrared data association (IrDA)), or a second network 2299 (a long-range communication network such as a cellular network, Internet, or computer network (LAN, WAN, etc.)). These various types of communication modules may be integrated into a single component (such as a single chip, etc.), or may be implemented as a plurality of separate components (multiple chips). The wireless communication module 2292 may identify and authenticate the electronic device 2201 in a communication network such as a first network 2298 and/or a second network 2299 using subscriber information (such as an international mobile subscriber identifier (IMSI) stored in the subscriber identification module 2296.

The antenna module 2297 may transmit a signal and/or power to the outside (such as another electronic device, etc.) or receive the signal and/or power from the outside. The antenna may include a radiator formed of a conductive pattern formed on the substrate (PCB, etc.). The antenna module 2297 may include one or a plurality of antennas. In an example case in which a plurality of antennas are included, an antenna suitable for a communication scheme used in a communication network such as a first network 2298 and/or a second network 2299 may be selected from among the plurality of antennas by the communication module 2290. A signal and/or power may be transmitted or received between the communication module 2290 and another electronic device through the selected antenna. Other components (RFIC, etc.) in addition to the antenna may be included as a part of the antenna module 2297.

Some of the components are connected to each other and may exchange signals (commands, data, etc.) via a communication scheme (bus, General Purpose Input and Output (GPIO), Serial Peripheral Interface (SPI), Mobile Industry Processor Interface (MIPI), etc.) and can interchange signals (commands, data, etc.) between peripherals.

The command or data may be transmitted or received between the electronic device 2201 and the external electronic device 2204 through the server 2208 connected to the second network 2299. Other electronic devices 2202 and 2204 may be the same or different types of devices as the electronic device 2201. All or some of the operations executed in the electronic device 2201 may be executed in one or more of the other electronic devices 2202 and 2204 and the sever 2208. In an example case in which the electronic device 2201 needs to perform a function or service, it may request one or more other electronic devices to perform part or all of the function or service instead of executing the function or service on its own. One or more other electronic devices receiving the request may execute an additional function or service related to the request and transmit a result of the execution to the electronic device 2201. To this end, cloud computing, distributed computing and/or client-server computing technology may be used.

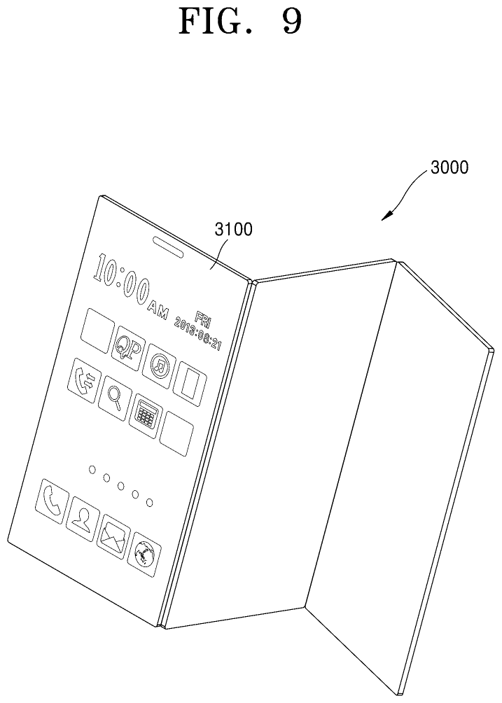

FIG. 9 illustrates an example in which a display device according to an embodiment is applied to a mobile device 3000. The mobile device 3000 may include a display device 3100. The display device 3100 may include one of the display devices 1000, 1001 and 1002 according to the embodiment of FIGS. 1 to 3. The display device 1300 may have a foldable structure and may be implemented as, for example, a multi-folder display. Here, although it is illustrated that the mobile device 3000 includes a folder-type display, the mobile device 3000 may also include a flat-panel type display.

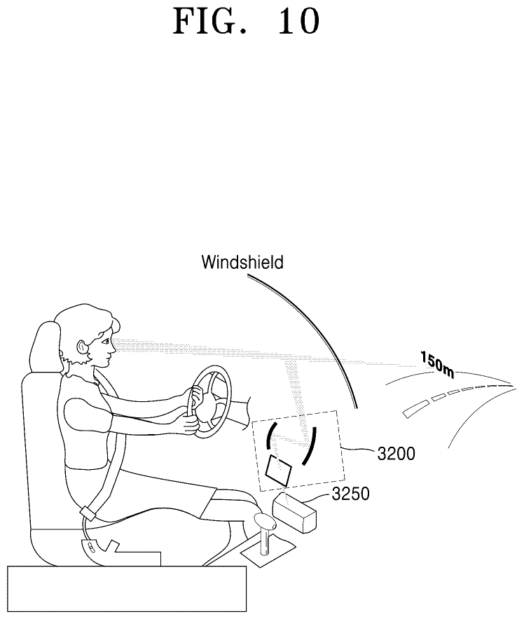

FIG. 10 illustrates an example in which a display device according to an embodiment is applied to a vehicle. The display device may be implemented as a head-up display device for a vehicle. The head-up display device may include a display device 3250 provided in one area of a vehicle and at least one optical path changing member 3200 that converts a path of light so that a driver may view an image generated by the display device 3250. The display device 3250 may include one of the display devices 1000, 1001 and 1002 according to the embodiment of FIGS. 1 to 3.

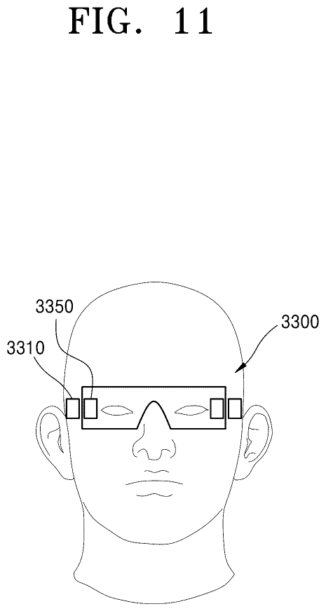

FIG. 11 illustrates an example in which a display device according to an embodiment is applied to augmented reality glasses or virtual reality glasses. The augmented reality glasses 3300 may include a projection system 3310 forming an image and at least one element 3350 guiding an image from the projection system 3310 to enter the user's eye. The at least one element 3350 may include an optical system. The projection system 3310 may include the display devices 1000, 1001 and 1002 according to the embodiments of FIGS. 1 to 3.

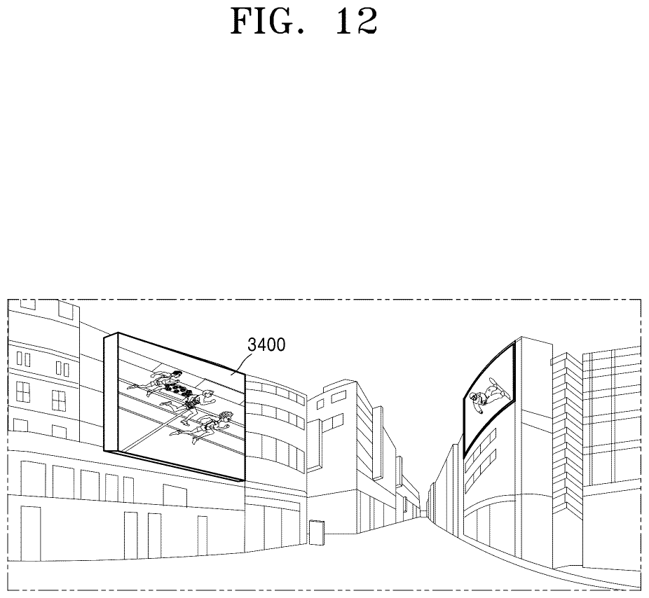

FIG. 12 illustrates an example in which a display device according to an embodiment is applied to a large signage. The signage 3400 may be used for outdoor advertisements using a digital information display and may control advertisement content, etc., through a communication network. The signage 3400 may be implemented by applying, for example, the display devices 1000, 1001 and 1002 according to the embodiments of FIGS. 1 to 3.

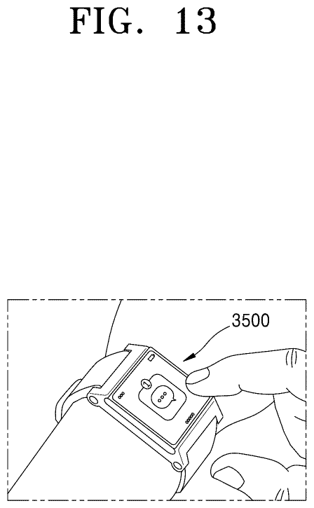

FIG. 13 illustrates an example in which a display device according to an embodiment is applied to a display of a wearable device. A display 3500 of the wearable device may be implemented by applying the display devices 1000, 1001 and 1002 according to the embodiments of FIGS. 1 to 3.

The display devices 1000, 1001 and 1002 according to the embodiments of FIGS. 1 to 3 may also be applied to various products such as a rollable TV and a stretchable display.

According to an embodiment of the disclosure, light emission efficiency of the display device may be improved by using different passivation layers in a plurality of light emitting elements. The display device and the method of manufacturing the same according to embodiments have been described with reference to embodiments shown in the drawings. According to the disclosed embodiments, the display device uses different passivation layers for a plurality of light emitting elements, thereby improving light emission efficiency.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first light emitting element comprising a first epitaxial structure, a second epitaxial structure, and a third epitaxial structure;
a second light emitting element comprising a fourth epitaxial structure, the second light emitting element spaced apart from the first light emitting element;
a first passivation layer provided on a sidewall of the first light emitting element; and
a second passivation layer provided on a sidewall of the second light emitting element,
wherein each of the first epitaxial structure, the second epitaxial structure, the third epitaxial structure and the fourth epitaxial structure comprises a first semiconductor layer of a first conductivity type, a carrier blocking layer, an active layer, and a second semiconductor layer of a second conductivity type are sequentially arranged.

2. The display device of claim 1, wherein the second passivation layer is further provided on a sidewall of the first passivation layer.

3. The display device of claim 2, wherein the first light emitting element is configured to emit red light and the first passivation layer comprises AlOₓN_{y}.

4. The display device of claim 1, wherein the second light emitting element is configured to emit blue light and the second passivation layer comprises Ta₂O₅.

5. The display device of claim 1, wherein a thickness of the first passivation layer is about 10 nm to about 30 nm.

6. The display device of claim 1, wherein a thickness of the second passivation layer is about 10 nm to about 30 nm.

7. The display device of claim 1, wherein the second passivation layer comprises a plurality of layers.

8. The display device of claim 1, further comprising an electron blocking layer provided between the active layer and the second semiconductor layer.

9. The display device of claim 1, further comprising a third light emitting element arranged between the first light emitting element and the second light emitting element and comprising a fifth epitaxial structure and a sixth epitaxial structure.

10. A method of manufacturing a display device, the method comprising:
forming a vertically stacked epitaxial structure by stacking a first epitaxial structure, a second epitaxial structure, and a third epitaxial structure, each of the first, second and third epitaxial structures having a first semiconductor layer of a first conductivity type, a carrier blocking layer, an active layer, and a second semiconductor layer of a second conductivity type are sequentially stacked on a substrate;
etching the vertically stacked epitaxial structure to form a first mesa structure and a second mesa structure, the first mesa structure including a first portion of the first epitaxial structure, a first portion of the second epitaxial structure, and a first portion of the third epitaxial structure and the second mesa structure including a second portion of the first epitaxial structure;
forming an electrode on the first mesa structure and the second mesa structure;
providing a first passivation layer on sidewalls of the first mesa structure and the second mesa structure;
removing the first passivation layer provided on the second mesa structure; and
providing a second passivation layer on the sidewall of the second mesa structure.

11. The method of claim 10, wherein the providing the second passivation layer further comprises providing the second passivation layer on a sidewall of the first passivation layer.

12. The method of claim 10, wherein the first mesa structure has a first height and the second mesa structure has a second height different from the first height.

13. The method of claim 10, further comprising, before the removing of the first passivation layer provided on the second mesa structure, forming a mask on the first passivation layer provided on the first mesa structure.

14. The method of claim 10, further comprising exposing the electrode by etching a portion of the first passivation layer and the second passivation layer.

15. The method of claim 10, further comprising forming an electron blocking layer between the active layer and the second semiconductor layer.

16. The method of claim 10, wherein the forming of the first mesa structure and the second mesa structure further comprises forming a third mesa structure between the first mesa structure and the second mesa structure, the third mesa structure comprising a third portion of the first epitaxial structure and a second portion of the second epitaxial structure.

17. The method of claim 10, wherein the first mesa structure forms a light emitting element configured to emit red light and the first passivation layer includes AlOₓN_{y}.

18. The method of claim 10, wherein the second mesa structure forms a light emitting element configured to emit blue light and the second passivation layer includes Ta₂O₅.

19. An augmented reality device comprising:
a projection system comprising a display device configured to form an image; and
an optical system for guiding the image from the projection system to the eyes of a user,
wherein the display device comprises:
a first light emitting element comprising a first epitaxial structure, a second epitaxial structure, and a third epitaxial structure;
a second light emitting element comprising a fourth epitaxial structure, the second light emitting element spaced apart from the first light emitting element;
a first passivation layer provided on a sidewall of the first light emitting element; and
a second passivation layer provided on a sidewall of the second light emitting element,
wherein each of the first epitaxial structure, the second epitaxial structure, the third epitaxial structure and the fourth epitaxial structure comprises a first semiconductor layer of a first conductivity type, a carrier blocking layer, an active layer, and a second semiconductor layer of a second conductivity type are sequentially arranged.

20. The augmented reality device of claim 19, wherein the first light emitting element is configured to emit red light, the second light emitting element is configured to emit blue light, the first passivation layer comprises AlOₓN_{y} and the second passivation layer comprises Ta₂O₅.
